(19) United States
(12) Patent Application Publication
(10) Pub. No.: US 2025/0118716 A1
(43) Pub. Date: Apr. 10, 2025

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Wei-Yu Chen, Taipei City (TW); Cheng-Shiuan Wong, Hsinchu City (TW); Chia-Shen Cheng, Hsinchu County (TW); Hsuan-Ting Kuo, Taichung City (TW); Hao-Jan Pei, Hsinchu (TW); Hsiu-Jen Lin, Hsinchu County (TW)

(73) Assignee: Taiwan Semiconductor Manufacturing Company, Ltd., Hsinchu (TW)

(21) Appl. No.: 18/484,405

(22) Filed: Oct. 10, 2023

(51) Int. Cl. H01L 25/16; H01L 21/56; H01L 23/00; H01L 23/31; H10B 80/00

(52) U.S. Cl. CPC H01L 25/167; H01L 21/561; H01L 23/3157; H01L 24/16; H01L 24/32; H01L 24/73; H10B 80/00; H01L 2224/16145; H01L 2224/16227; H01L 2224/32145; H01L 2224/73204

(57) ABSTRACT

A semiconductor package includes a semiconductor element, at least one electronic die, at least one optical die, an encapsulant, and a substrate. The semiconductor element has a first side and a second side opposing to the first side. The at least one electronic die is disposed over the first side. The at least one optical die is disposed over the first side and next to the at least one electronic die. The encapsulant is disposed on the first side and covers the at least one electronic die, where a sidewall of the at least one optical die is distant from the encapsulant, and a sidewall of the encapsulant is aligned with a sidewall of the semiconductor element. The substrate is disposed over the second side, where the at least one electronic die is electrically coupled to the substrate and the at least one optical die through the semiconductor element.

### BACKGROUND

Developments in shrinking sizes of semiconductor devices and electronic components make the integration of more devices and components into a given volume possible and lead to high integration density of various semiconductor devices and/or electronic components.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1, FIG. 2, FIG. 3, FIG. 4, FIG. 5, FIG. 6, FIG. 7, FIG. 8, FIG. 9, FIG. 15, FIG. 16, FIG. 17 and FIG. 18 are schematic plane or cross-sectional views of various stages in a manufacturing method of a semiconductor package in accordance with some embodiments of the disclosure.

FIG. 10 is a schematically enlarged, cross-sectional view showing a cutting region which is a predetermined location of an optical die integrated with a semiconductor package in accordance with some embodiments of the disclosure.

FIG. 11 through FIG. 14 are schematically enlarged, cross-sectional views showing various embodiments of an uppermost surface of an encapsulant and an uppermost surface of a solder region at the cutting region of FIG. 10.

FIG. 19 is a schematically enlarged, cross-sectional view showing a bonding configuration between a semiconductor element and an optical die integrated with a semiconductor package in accordance with some embodiments of the disclosure.

FIG. 20 through FIG. 21 are schematically enlarged, cross-sectional views showing various embodiments of an uppermost surface of an encapsulant near the bonding configuration of FIG. 19.

FIG. 22 is a flow chart illustrating a method of manufacturing a semiconductor package in accordance with some embodiments of the disclosure.

FIG. 23 is a flow chart illustrating a part of a method of manufacturing a semiconductor package in accordance with some embodiments of the disclosure.

FIG. 24 through FIG. 25 are schematic cross-sectional views of various stages in a part of a manufacturing method of a semiconductor package in accordance with some embodiments of the disclosure, showing a cutting region which is a predetermined location of an optical die integrated with the semiconductor package.

FIG. 26 through FIG. 29 are schematically enlarged, cross-sectional views showing various embodiments of an uppermost surface of an encapsulant and an uppermost surface of a solder region at the cutting region of FIG. 25.

FIG. 30 is a schematically enlarged, cross-sectional view of an intermediate stage in a manufacturing method of a semiconductor package in accordance with some embodiments of the disclosure, showing a cutting region which is a predetermined location of an optical die integrated with the semiconductor package.

FIG. 31 through FIG. 34 are schematically enlarged, cross-sectional views showing various embodiments of an uppermost surface of an encapsulant and an uppermost surface of a solder region at the cutting region of FIG. 30.

FIG. 35 is a schematically enlarged, cross-sectional view showing a bonding configuration between a semiconductor element and an optical die integrated with a semiconductor package in accordance with some embodiments of the disclosure.

FIG. 36 through FIG. 37 are schematically enlarged, cross-sectional views showing various embodiments of an uppermost surface of an encapsulant near the bonding configuration of FIG. 35.

FIG. 38 is a schematically enlarged, cross-sectional view showing a bonding configuration between a semiconductor element and an optical die integrated with a semiconductor package in accordance with some embodiments of the disclosure.

FIG. 39 through FIG. 40 are schematically enlarged, cross-sectional views showing various embodiments of an uppermost surface of an encapsulant near the bonding configuration of FIG. 38.

FIG. 41 through FIG. 48 are schematically plane views showing various embodiments of an arrangement of an optical die and a semiconductor die included in a semiconductor package in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The specific embodiment(s) described herein is related to a semiconductor package (or a semiconductor device or structure) having a stacked structure with an optical die (or chip/chiplet/package) equipped therewith and a method of manufacturing the same, and is not intended to limit the scope of the disclosure. Due to the optical die is integrated with the semiconductor package, the performance of the semiconductor package is improved by enabling the bandwidth enlargement and faster data transfer over a longer distance. In addition, the optical die being integrated to the semiconductor package is implemented by trimming an encapsulant to excavate a per-determined location for the optical die, therefore the manufacturing process is simple and the manufacturing cost is reduced.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

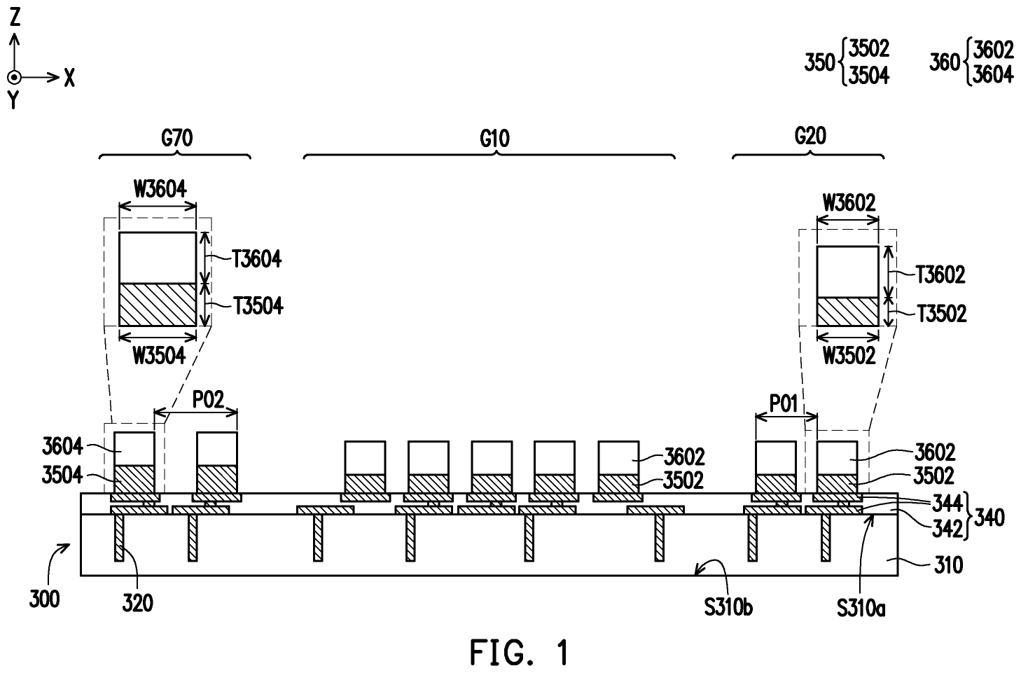

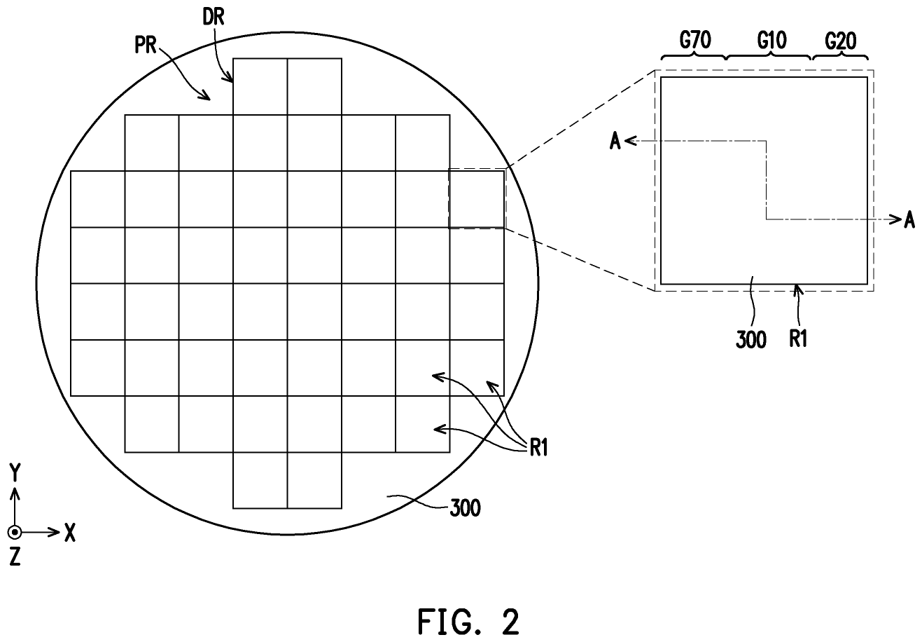

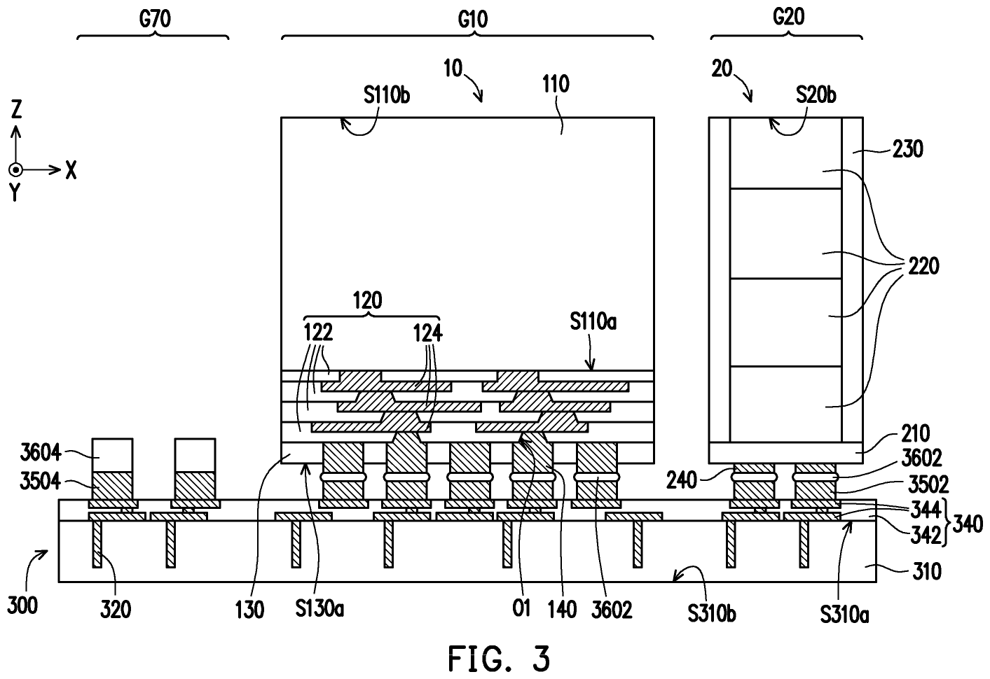

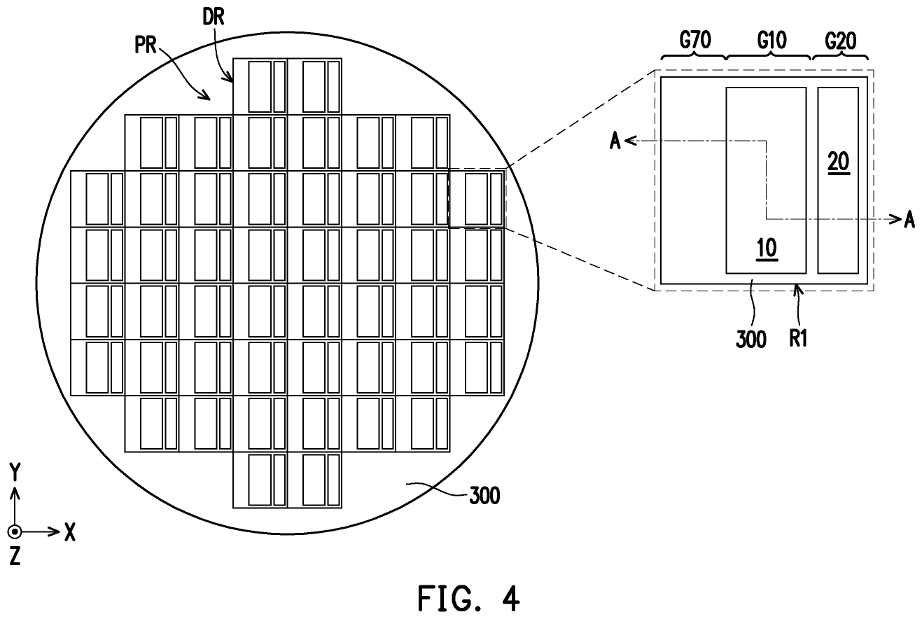

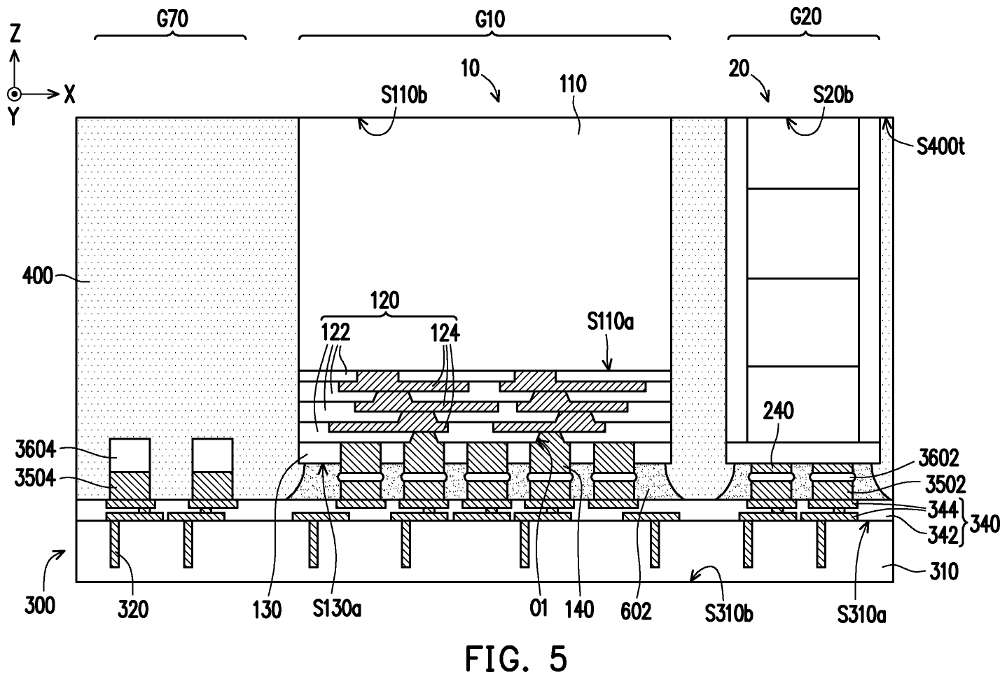

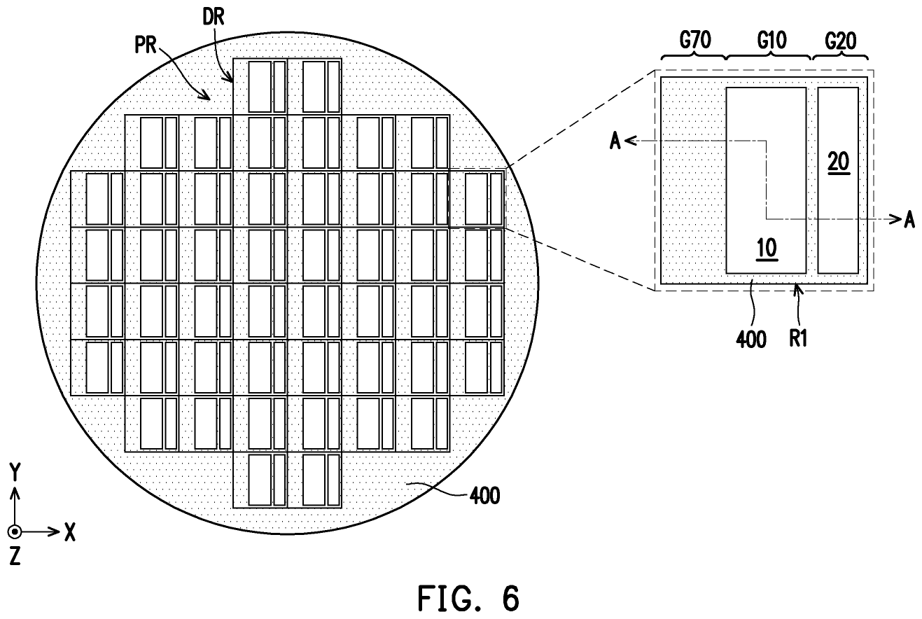

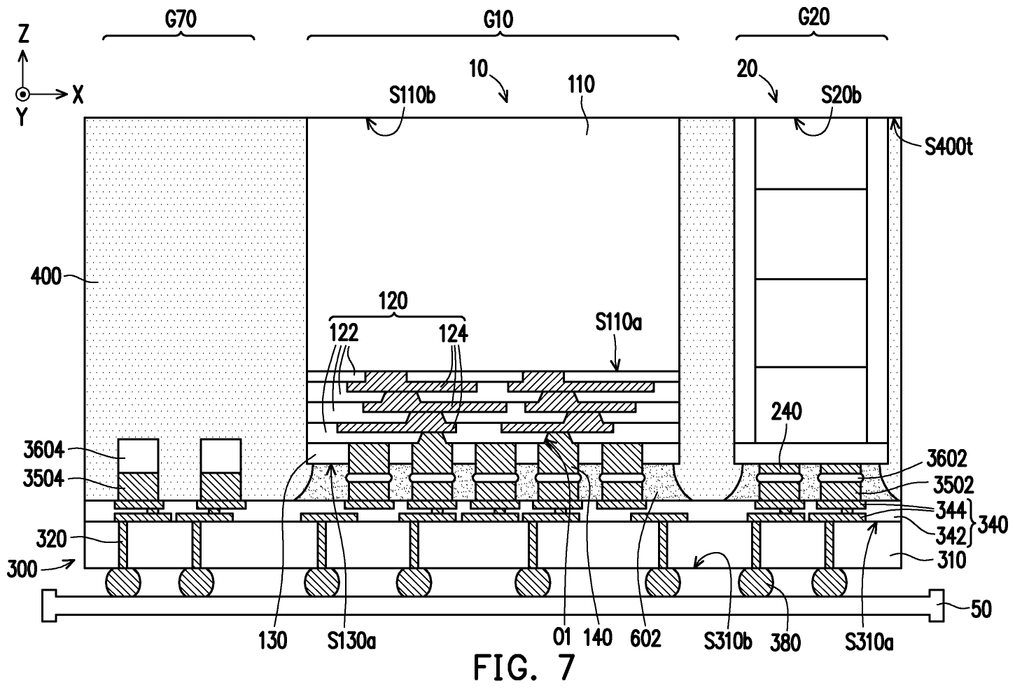

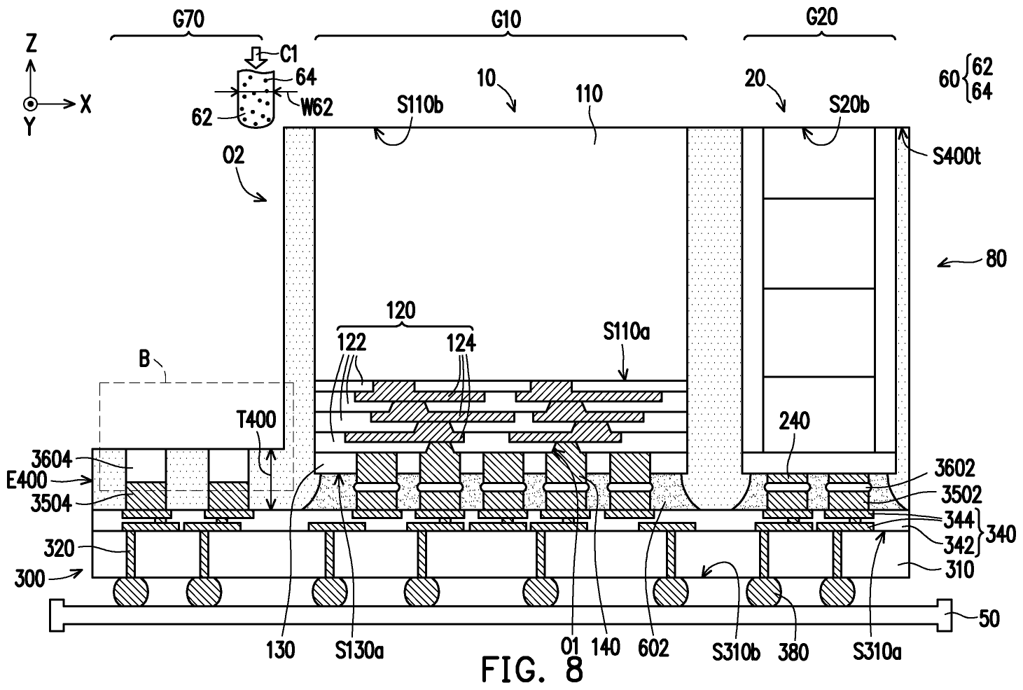

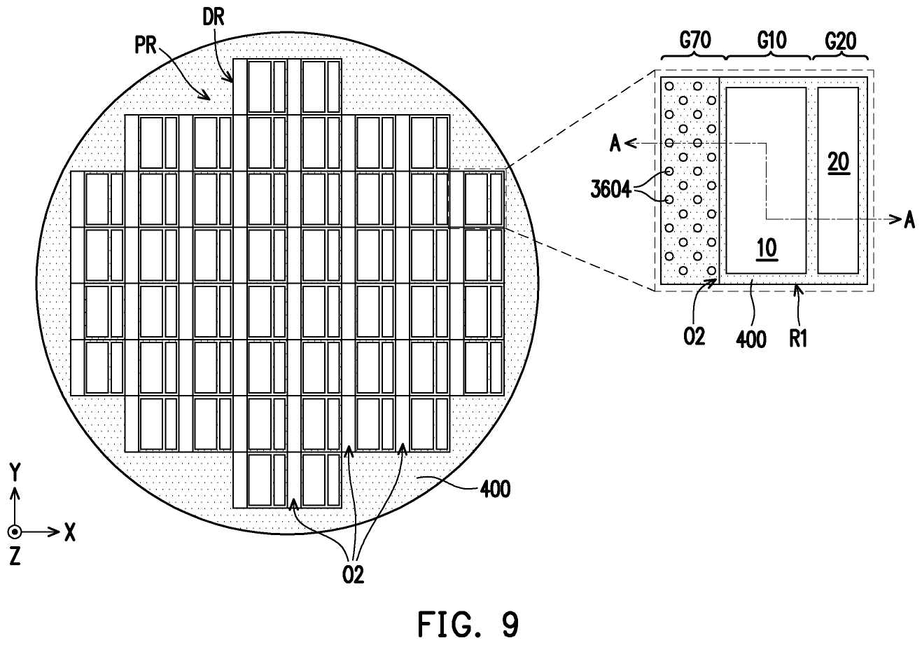

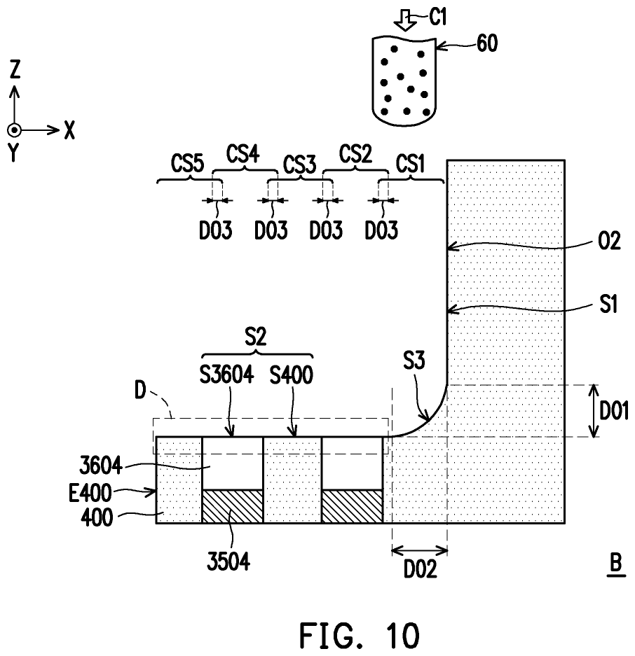

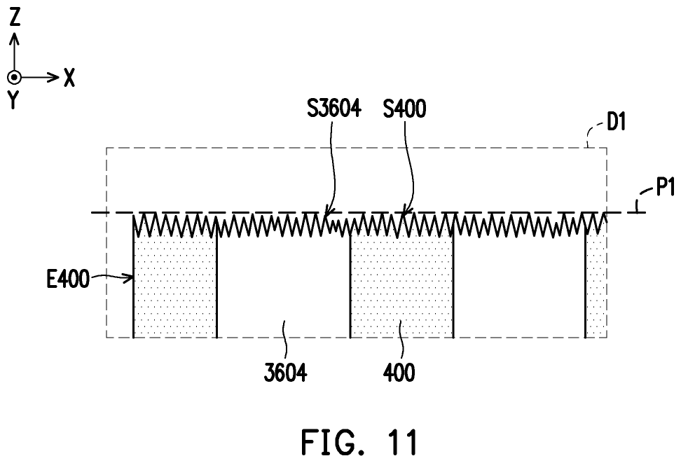

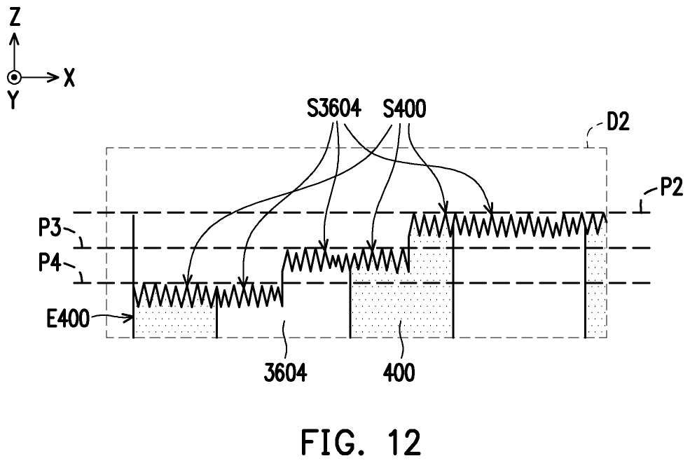

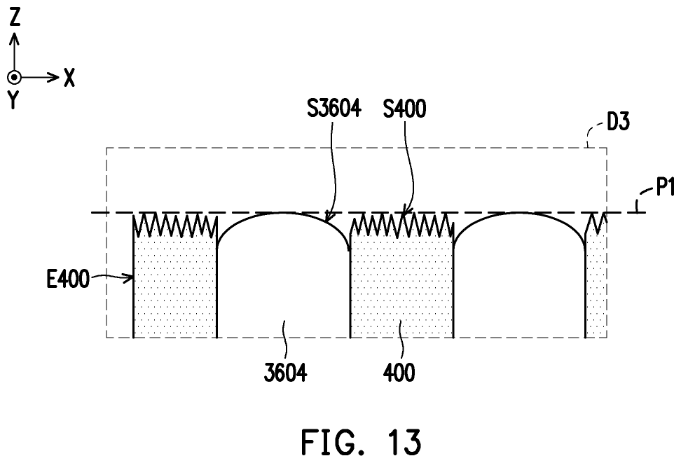

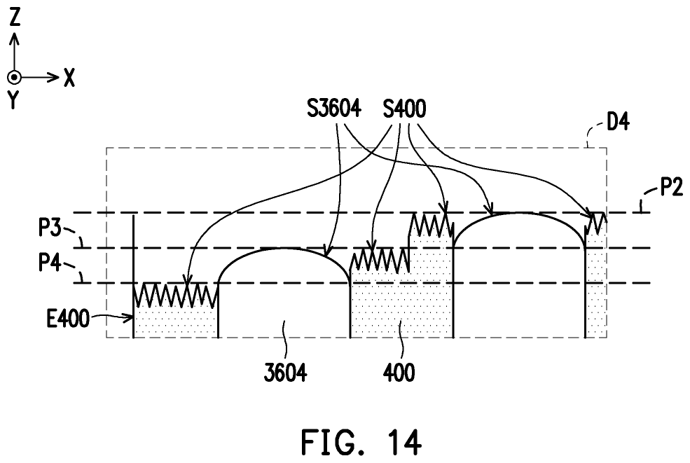

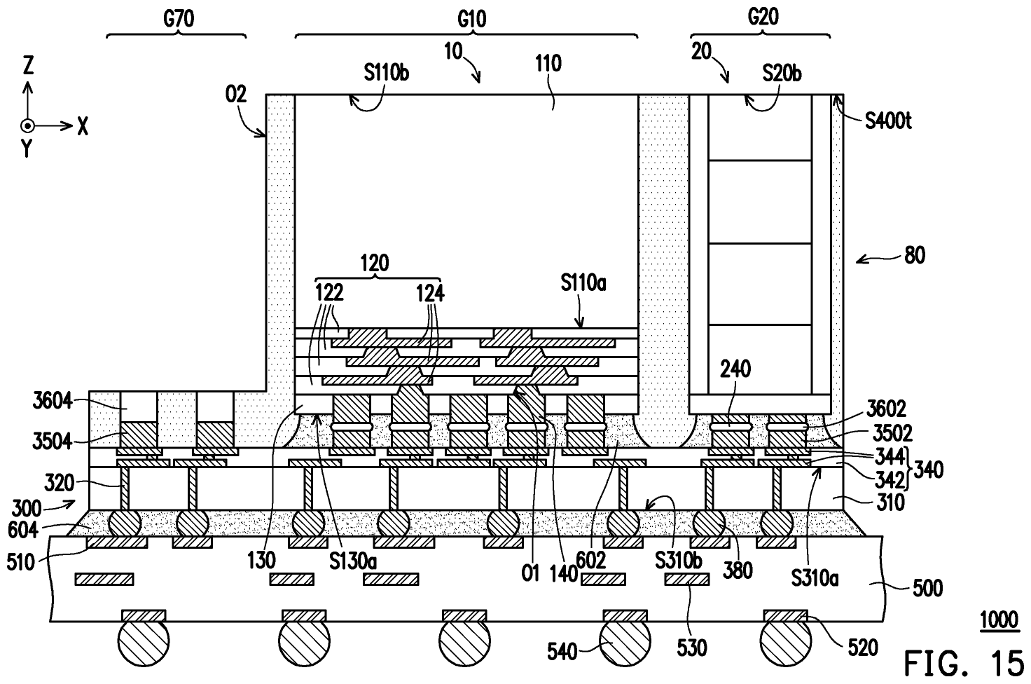

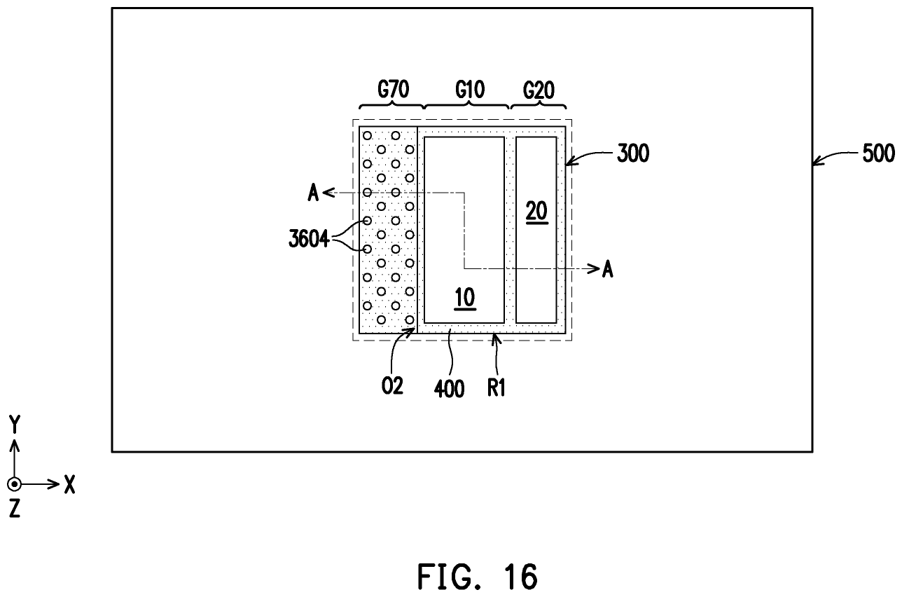

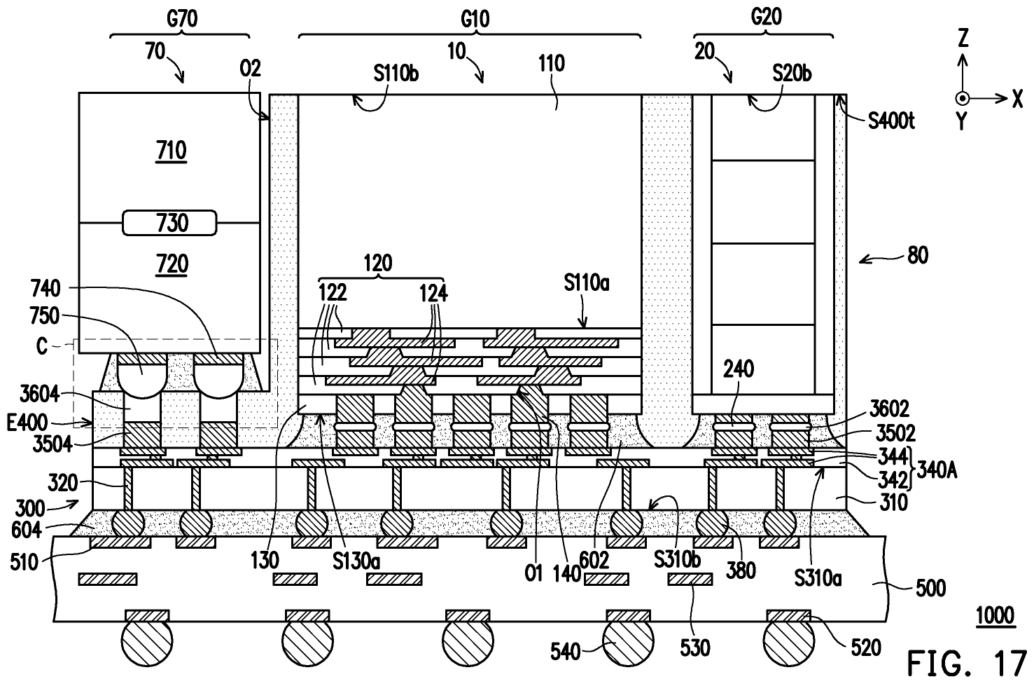

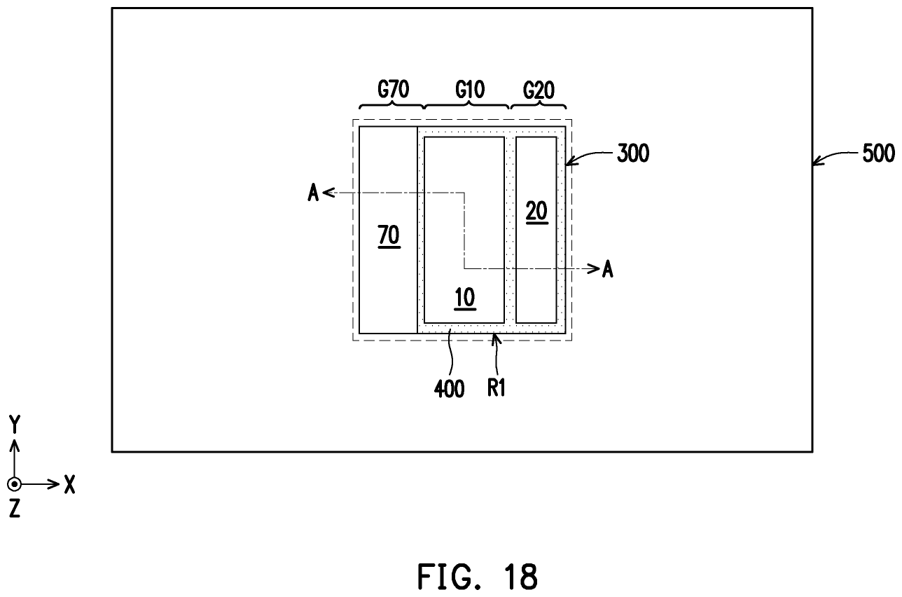

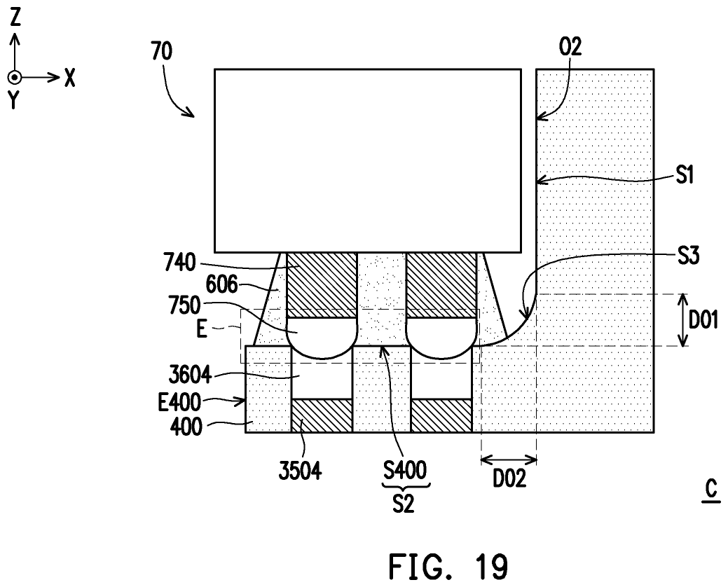

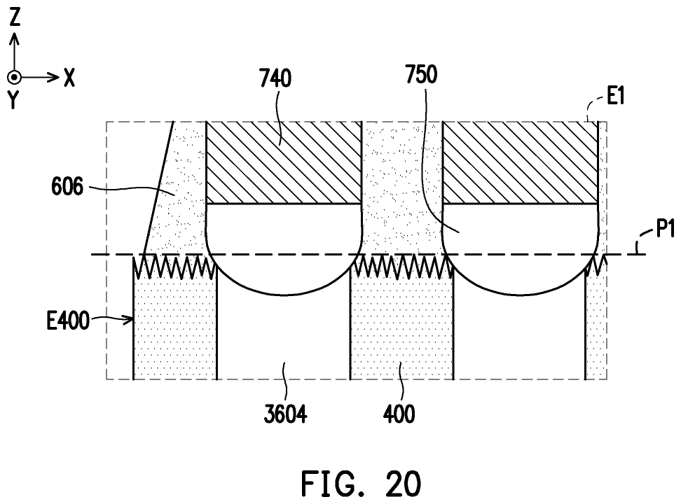

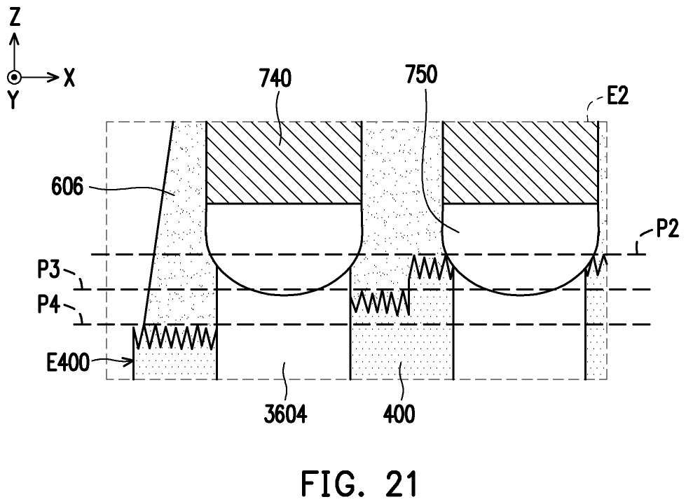

FIG. 1, FIG. 2, FIG. 3, FIG. 4, FIG. 5, FIG. 6, FIG. 7, FIG. 8, FIG. 9, FIG. 15, FIG. 16, FIG. 17 and FIG. 18 are schematic plane or cross-sectional views of various stages in a manufacturing method of a semiconductor package 1000 in accordance with some embodiments of the disclosure, where the cross-sectional views of FIG. 1, FIG. 3, FIG. 5, FIG. 7, FIG. 8, FIG. 15 and FIG. 17 are taken along a line A-A depicted in the plane views of FIG. 2, FIG. 4, FIG. 6, FIG. 9, FIG. 16 and FIG. 18. FIG. 10 is a schematically enlarged, cross-sectional view showing a cutting region which is a predetermined location of an optical die integrated with the semiconductor package 1000 of FIG. 8, which is outlined by a dashed-box B depicted in FIG. 8. FIG. 11 through FIG. 14 are schematically enlarged, cross-sectional views showing various embodiments of an uppermost surface of an encapsulant and an uppermost surface of a solder region at the cutting region of FIG. 10, which are outlined by a dashed-box D depicted in FIG. 10 (e.g., a dashed-box D1 in FIG. 11, a dashed-box D2 in FIG. 12, a dashed-box D3 in FIG. 13, and/or a dashed-box D4 in FIG. 14). FIG. 19 is a schematically enlarged, cross-sectional view showing a bonding configuration between a semiconductor element and an optical die integrated with the semiconductor package 1000 of FIG. 17, where the bonding configuration is outlined by a dashed-box C depicted in FIG. 17. FIG. 20 through FIG. 21 are schematically enlarged, cross-sectional views showing various embodiments of an uppermost surface of an encapsulant near the bonding configuration of FIG. 19, which are outlined by a dashed-box E depicted in FIG. 19 (e.g., a dashed-box E1 in FIG. 20 and/or a dashed-box E2 in FIG. 21). The embodiments are intended to provide further explanations but are not used to limit the scope of the disclosure.

Referring to FIG. 1 and FIG. 2, in some embodiments, a semiconductor element 300 is provided. In some embodiments, the semiconductor element 300 is an interposer. In some embodiments, the semiconductor element 300 is an integrated circuit device or an element including a silicon substrate. In some embodiments, if considering a top or plane view (e.g., a X-Y plane) along a direction Z, the semiconductor element 300 is in a wafer or panel form. The semiconductor element 300 may be in a form of wafer-size having a diameter of about 4 inches or more. The semiconductor element 300 may be in a form of wafer-size having a diameter of about 6 inches or more. The semiconductor element 300 may be in a form of wafer-size having a diameter of about 8 inches or more. Or alternatively, the semiconductor element 300 may be in a form of wafer-size having a diameter of about 12 inches or more. In some embodiments, the semiconductor element 300 includes a device region DR and a peripheral region PR surrounding the device region DR, where the device region DR include a plurality of regions R1 arranged in a form of an array along a direction X and a direction Y, where each region R1 is a positioning (or pre-determined) location for placing semiconductor dies to be included in the semiconductor package 1000. The direction X, the direction Y and the direction Z may be different from each other. For example, the direction X is perpendicular to the direction Y, and the direction X and the direction Y are independently perpendicular to the direction Z, as shown in FIG. 1. In the disclosure, the direction Z may be referred to as a stacking direction, and the X-Y plane defined by the direction X and the direction Y may be referred to as the plane view or top view.

In some embodiments, each of the regions R1 includes two or more sections for disposing the semiconductor dies. As shown in FIG. 2, each of the regions R1 includes three sections (such as G10, G20 and G70) for disposing the semiconductor dies in subsequent processes. However, the disclosure is not limited thereto, the number of sections for disposing the semiconductor dies included in each region R1 may be two, three, fourth, or more, depending on the demand and the design requirement. For example, the number of section G10 in the region R1 may be one or more than one, the number of section G20 in the region R1 may be zero, one or more than one, and the number of section G70 in the region R1 may be one or more than one; depending on demand and design layout. As shown in FIG. 1, in some embodiments, the semiconductor element 300 includes a substrate 310, a plurality of through vias 320, a redistribution circuit structure 340, a plurality of connecting pads 350, and a plurality of solder regions 360.

In some embodiments, the substrate 310 is a wafer, such as a bulk semiconductor substrate, a silicon-on-insulator (SOI) substrate, a multi-layered semiconductor substrate, or the like. The semiconductor material of the substrate 310 may be silicon, germanium; a compound semiconductor including silicon carbide, gallium arsenic, gallium phosphide, indium phosphide, indium arsenide, and/or indium antimonide; an alloy semiconductor including silicon germanium (SiGe), GaAsP, AlInAs, AlGaAs, GaInAs, GaInP, and/or GaInAsP; or combinations thereof. The alloy SiGe may be formed over a silicon substrate. The SiGe substrate may be strained. In an alternative embodiment, other substrates, such as multi-layered or gradient substrates, may also be used. The substrate 310 may be doped or undoped. The substrate 310 may include a wide variety of components (not shown) (also referred to as semiconductor components) formed therein. The components may include active components, passive components, or a combination thereof. The components may include integrated circuits devices. The components may include transistors, capacitors, resistors, diodes, photodiodes, fuse devices, jumpers, inductors, or other similar devices. The functions of the components may include memory, processors, sensors, amplifiers, power distribution, input/output circuitry, or the like. The components each may be referred to as a semiconductor component of the disclosure. For example, the active components and/or passive components (such as transistors, capacitors, resistors, diodes, photodiodes, fuse devices, jumpers, inductors, and the like) are formed in and/or on a surface S310a of the substrate 310. In some embodiments, the surface S310a is referred to as an active surface (or a front side) of the substrate 310. Alternatively, the substrate 310 may be substantially free of active components and passive components, and merely provide routing functions.

In some embodiments, through vias 320 are formed in the substrate 310 to extend from the surface S310a of the substrate 310 to a position inside the substrate 310 and is not exposed by a surface S310b of the substrate 310, where the surface S310b is opposite to the surface S310a along the stacking direction Z. The through vias 320 may be formed by forming recesses in the substrate 310 (by, for example, etching, milling, laser techniques, a combination thereof, and/or the like) and depositing a conductive material in the recesses. The conductive material may be formed by an electro-chemical plating process, chemical vapor deposition (CVD), atomic layer deposition (ALD), physical vapor deposition (PVD), a combination thereof, and/or the like. Examples of conductive materials are copper, tungsten, aluminum, silver, gold, a combination thereof, and/or the like. An optional thin dielectric layer (not shown) may be formed in the recesses, such as by using an oxidation technique, to separate the substrate 310 and the through vias 320. A thin barrier layer (not shown) may be conformally formed in the recesses, such as by CVD, ALD, PVD, thermal oxidation, a combination thereof, and/or the like, to separate the substrate 310 and the optional thin dielectric layer. The thin barrier layer may comprise a nitride or an oxynitride, such as titanium nitride, titanium oxynitride, tantalum nitride, tantalum oxynitride, tungsten nitride, a combination thereof, and/or the like. Excess conductive material and the thin barrier layer are removed from the surface S310a of the substrate 310 by, for example, chemical mechanical polishing (CMP) process. Thus, the through vias 320 may comprise a conductive material, a thin barrier layer between the conductive material and the substrate 310 and an optional dielectric layer between the thin barrier layer and the substrate 310. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, a redistribution circuit structure 340 is formed on the surface S310a of the substrate 310, and is electrically connected to the substrate 310. In certain embodiments, the redistribution circuit structure 340 includes a dielectric structure 342 and one or more metallization layers 344 arranged therein for providing routing functionality. In some embodiments, the dielectric structure 342 includes one or more dielectric layers, such that the dielectric layers and the metallization layer 344 are sequentially formed, and one metallization layer 344 is sandwiched between two dielectric layers. As shown in FIG. 1, portions of a top surface of a topmost layer of the metallization layers 344 are respectively exposed by openings formed in a topmost portion (e.g., a topmost dielectric layer) of the dielectric structure 342, and portions of a bottom surface of a bottommost layer of the metallization layers 344 are respectively exposed by openings formed in a bottommost portion (e.g., a bottommost dielectric layer) of the dielectric structure 342. However, the disclosure is not limited thereto.

The material of the dielectric structure 342 may include silicon oxide, silicon nitride, silicon oxy-nitride, or any other suitable dielectric materials, and may be formed by deposition or the like. The metallization layers 344 may be or include patterned copper layers or other suitable patterned metal layers, and may be formed by electroplating or deposition. However, the disclosure is not limited thereto. Alternatively, the metallization layers 344 may be formed by dual-damascene method. The numbers of the metallization layers and the dielectric layers included in the redistribution circuit structure 340 is not limited thereto, and may be designated and selected based on the demand and design layout.

As shown in FIG. 1, the through vias 320 are connected to the portions of the bottom surface of the bottommost layer of the metallization layers 344 respectively exposed by the openings formed in the bottommost dielectric layer of the dielectric structure 342. In other words, the redistribution circuit structure 340 is electrically connected to the through vias 320. The redistribution circuit structure 340 may further be electrically connected to the active and/or passive components embedded in the substrate 310 or formed on the surface S310a of the substrate 310 (if any). In some embodiments, through the redistribution circuit structure 340, the through vias 320 are electrically coupled to the substrate 310 and/or the active and/or passive components embedded in the substrate 310 or formed on the surface S310a of the substrate 310 (if any).

Continued on FIG. 1, in some embodiments, the connecting pads 350 are formed on the portions of the top surface of the topmost layer of the metallization layers 344 respectively exposed by the openings formed in the topmost dielectric layer of the dielectric structure 342, where the connecting pads 350 are electrically coupled to the redistribution circuit structure 340 by directly connecting the metallization layers 344. For example, as shown in FIG. 1, the connecting pads 350 includes a first group of connecting pads 3502 disposed over the substrate 310 within the sections G10 and G20 and a second group of connecting pads 3504 disposed over the substrate 310 within the section G70, where the first group of connecting pads 3502 and the second group of connecting pads 3504 are disposed on (e.g., in physical contact with) the portions of the top surface of the topmost layer of the metallization layers 344 respectively exposed by the openings formed in the topmost dielectric layer of the dielectric structure 342 to establish electrical connections therebetween. The material of the connecting pads 350 may be metal, metal alloy, or the like, which may be formed by any other suitable method and processes based on the demand. For example, the connecting pads 350 include copper pads, copper alloy pads, or the like.

For example, the first group of connecting pads 3502 are electrically connected to the through vias 320 through the redistribution circuit structure 340. The first group of connecting pads 3502 may further be electrically connected to the active and/or passive components embedded in the substrate 310 or formed on the surface S310a of the substrate 310 (if any) through the redistribution circuit structure 340. In some embodiments, through the redistribution circuit structure 340, the first group of connecting pads 3502 are electrically coupled to each other, in part or all. In some embodiments, a pitch P01 between two adjacent connecting pads 3502 is approximately in a range from 1 μm to 5 μm, although other suitable pitch may alternatively be utilized. A thickness T3502 of the connecting pads 3502 is approximately in a range from 1 μm to 10 μm, although other suitable thickness may alternatively be utilized. A width W3502 of the connecting pads 3502 is approximately in a range from 1 μm to 10 μm, although other suitable width may alternatively be utilized.

For example, the second group of connecting pads 3504 are electrically connected to the through vias 320 through the redistribution circuit structure 340. The second group of connecting pads 3504 may further be electrically connected to the active and/or passive components embedded in the substrate 310 or formed on the surface S310a of the substrate 310 (if any) through the redistribution circuit structure 340. In some embodiments, through the redistribution circuit structure 340, the second group of connecting pads 3504 are electrically coupled to each other, in part or all. In some embodiments, a pitch P02 between two adjacent connecting pads 3504 is approximately in a range from 1 μm to 5 μm, although other suitable pitch may alternatively be utilized. A thickness T3504 of the connecting pads 3504 is approximately in a range from 1 μm to 10 μm, although other suitable thickness may alternatively be utilized. A width W3504 of the connecting pads 3504 is approximately in a range from 1 μm to 10 μm, although other suitable width may alternatively be utilized.

In addition, through the redistribution circuit structure 340, at least some of the first group of connecting pads 3502 may be electrically coupled to some of the second group of connecting pads 3504. The pitch P02 may be different from the pitch PO1. In a non-limiting example, the pitch PO2 is greater than the pitch PO1, as shown in FIG. 1. In another non-limiting example, the pitch P02 may be less than the pitch PO1. Alternatively, the pitch P02 may be substantially equal to the pitch PO1. The thickness T3504 may be different from the thickness T3502. In a non-limiting example, the thickness T3504 is greater than the thickness T3502, as shown in FIG. 1. In another non-limiting example, the thickness T3504 may be less than the thickness T3502. Alternatively, the thickness T3504 may be substantially equal to the thickness T3502. The width W3504 may be different from the width W3502. In a non-limiting example, the width W3504 is greater than the width W3502, as shown in FIG. 1. In another non-limiting example, the width W3504 may be less than the width W3502. Alternatively, the width W3504 may be substantially equal to the width W3502.

In some embodiments, the solder regions 360 are formed on the connecting pads 350, where the solder regions 360 are electrically coupled to the connecting pads 350 by direct contacts. For example, as shown in FIG. 1, the solder regions 360 includes a first group of solder regions 3602 disposed over the substrate 310 within the sections G10 and G20 and a second group of solder regions 3604 disposed over the substrate 310 within the section G70, where the first group of solder regions 3602 and the second group of solder regions 3604 are respectively disposed on (e.g., in physical contact with) the first group of connecting pads 3502 and the second group of connecting pads 3504 to establish electrical connections therebetween. The solder may include lead or be lead-free, and may include Sn—Ag, Sn—Cu, Sn—Ag—Cu, or the like.

For example, the first group of solder regions 3602 are electrically connected to the through vias 320 through the redistribution circuit structure 340 and the first group of connecting pads 3502. The first group of solder regions 3602 may further be electrically connected to the active and/or passive components embedded in the substrate 310 or formed on the surface S310a of the substrate 310 (if any) through the redistribution circuit structure 340 and the first group of connecting pads 3502. In some embodiments, through the redistribution circuit structure 340 and the first group of connecting pads 3502, the first group of solder regions 3602 are electrically coupled to each other, in part or all. In some embodiments, the pitch P01 is also adopted by the solder regions 3602, although other suitable pitch may alternatively be utilized. A thickness T3602 of the solder regions 3602 is approximately in a range from 1 μm to 10 μm, although other suitable thickness may alternatively be utilized. A width W3602 of the solder regions 3602 is approximately in a range from 1 μm to 10 μm, although other suitable width may alternatively be utilized.

For example, the second group of solder regions 3604 are electrically connected to the through vias 320 through the redistribution circuit structure 340 and the second group of connecting pads 3504. The second group of solder regions 3604 may further be electrically connected to the active and/or passive components embedded in the substrate 310 or formed on the surface S310a of the substrate 310 (if any) through the redistribution circuit structure 340 and the second group of connecting pads 3504. In some embodiments, through the redistribution circuit structure 340 and the second group of connecting pads 3504, the second group of solder regions 3604 are electrically coupled to each other, in part or all. In some embodiments, the pitch PO2 is also adopted by the solder regions 3604, although other suitable pitch may alternatively be utilized. A thickness T3604 of the solder regions 3604 is approximately in a range from 1 μm to 10 μm, although other suitable thickness may alternatively be utilized. A width W3604 of the solder regions 3604 is approximately in a range from 1 μm to 10 μm, although other suitable width may alternatively be utilized.

In addition, through the redistribution circuit structure 340 and the connecting pads 350, at least some of the first group of connecting pads 3502 may be electrically coupled to some of the second group of connecting pads 3504. The thickness T3604 may be different from the thickness T3602. In a non-limiting example, the thickness T3604 is greater than the thickness T3602, as shown in FIG. 1. In another non-limiting example, the thickness T3604 may be less than the thickness T3602. Alternatively, the thickness T3604 may be substantially equal to the thickness T3602. The width W3604 may be different from the width W3602. In a non-limiting example, the width W3604 is greater than the width W3602, as shown in FIG. 1. In another non-limiting example, the width W3604 may be less than the width W3602. Alternatively, the width W3604 may be substantially equal to the width W3602.

In some embodiments, the connecting pads 3502 and the solder regions 3602 are collectively referred to as conductive pads of the semiconductor element 300. In some embodiments, the connecting pads 3504 and the solder regions 3604 are collectively referred to as conductive pads of the semiconductor element 300, as well. However the disclosure is not limited thereto; alternatively, solder regions 3602 and/or 3604 may be omitted. In such embodiments, the connecting pads 3502, 3504 can be referred to as conductive pads of the semiconductor element 300, independently.

Referring to FIG. 3 and FIG. 4, in some embodiments, at least one semiconductor die 10 is disposed over the substrate 310 of the semiconductor element 300 within the section G10 of region R1, and at least one semiconductor die 20 is disposed over the substrate 310 of the semiconductor element 300 within the section G20 of region R1. For illustrative purposes and simplicity, only one semiconductor die 10 and only one semiconductor die 20 are shown in FIG. 3 and FIG. 4, however, the number of semiconductor die 10 in each section G10 may be one or more than one, and the number of semiconductor die 20 in each section G20 may be one or more than one. The disclosure is not limited thereto.

In some embodiments, the semiconductor die 10 includes a semiconductor substrate 110, an interconnect structure 120 disposed on the semiconductor substrate 110, a passivation layer 130 disposed on the interconnect structure 120, and a plurality of conductive vias 140 penetrating through the passivation layer 130 and disposed on the interconnect structure 120. As shown in FIG. 3, the semiconductor substrate 110 has a frontside surface S110a and a backside surface S110b opposite to the frontside surface S110a, and the interconnect structure 120 is located on the frontside surface S110a of the semiconductor substrate 110, where the interconnect structure 120 is sandwiched between the semiconductor substrate 110 and the passivation layer 130 and sandwiched between the semiconductor substrate 110 and the conductive vias 140, for example.

In some embodiments, the semiconductor substrate 110 is a silicon substrate including active components (e.g., transistors and/or memories such as N-type metal-oxide semiconductor (NMOS) and/or P-type metal-oxide semiconductor (PMOS) devices, or the like) and/or passive components (e.g., resistors, capacitors, inductors or the like) formed therein. In some embodiments, such active components and passive components are formed in a front-end-of-line (FEOL) process. In an alternative embodiment, the semiconductor substrate 110 is a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. The disclosure is not limited thereto.

The semiconductor substrate 110 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. For example, the semiconductor substrate 110 has an active surface (e.g., the frontside surface S110a), sometimes called a top side, and a non-active surface (e.g., the backside surface S110b), sometimes called a bottom side.

In some embodiments, the interconnect structure 120 includes one or more inter-dielectric layers 122 and one or more patterned conductive layers 124 stacked alternately. For examples, the inter-dielectric layers 122 are silicon oxide layers, silicon nitride layers, silicon oxy-nitride layers, or dielectric layers formed by other suitable dielectric materials, and are formed by deposition or the like. For examples, the patterned conductive layers 124 are patterned copper layers or other suitable patterned metal layers, and are formed by electroplating or deposition. However, the disclosure is not limited thereto. Alternatively, the patterned conductive layers 124 may be formed by dual-damascene method. The number of the inter-dielectric layers 122 and the number of the patterned conductive layers 124 may be less than or more than what is depicted in FIG. 3, and may be designated and selected based on the demand and/or design layout; the disclosure is not specifically limited thereto. In some embodiments, the interconnect structure 120 is formed in a back-end-of-line (BEOL) process.

In certain embodiments, as shown in FIG. 3, the patterned conductive layers 124 are sandwiched between the inter-dielectric layers 122, where a surface of the outermost layer of the patterned conductive layers 124 is at least partially exposed by a plurality of openings O1 formed in an outermost layer of the inter-dielectric layers 122 to connect to later formed component(s) for electrical connection (e.g. with the conductive vias 140), and a surface of an innermost layer of the patterned conductive layers 124 is at least partially exposed by a plurality of openings (no marked) formed in an innermost layer of the inter-dielectric layers 122 and electrically connected to the active components and/or passive components included in the semiconductor substrate 110. The shape and number of the openings formed in the outermost layer of the inter-dielectric layers 122 and the shape and number of the openings formed in the innermost layer of the inter-dielectric layers 122 are not limited in the disclosure, and may be designated based on the demand and/or design layout.

In some embodiments, as shown in FIG. 3, the passivation layer 130 is formed on the interconnect structure 120, where parts of the interconnect structure 120 is covered by and in contact with the passivation layer 130, and rest of the interconnect structure 120 is accessibly revealed by the passivation layer 130. As shown in FIG. 3, the passivation layer 130 has a substantially planar surface (e.g. an outermost surface S130a), for example. In certain embodiments, the outermost surface S130a of the passivation layer 130 is leveled and may have a high degree of planarity and flatness, which is beneficial for the later-formed layers/elements (e.g. the conductive vias 140). In some embodiments, the passivation layer 130 includes a polyimide (PI) layer, a polybenzoxazole (PBO) layer, a silicon dioxide based (non-organic) layer or other suitable polymer (or organic) layer, and is formed by deposition or the like. The disclosure is not limited thereto. The disclosure does not specifically limit a thickness of the passivation layer 130 as long as the passivation layer 130 can maintain its high degree of planarity and flatness. In the disclosure, the outermost surface S130a of the passivation layer 130 may be referred to as a front (or active) side of the semiconductor die 10.

In some embodiments, the conductive vias 140 are formed on the interconnect structure 120 and over the semiconductor substrate 110, and sidewalls of the conductive vias 140 are wrapped around by the passivation layer 130, as least partially. In some embodiments, as shown in FIG. 3, the conductive vias 140 each penetrate through the passivation layer 130 and extend into the openings O1 formed in the outermost layer of the inter-dielectric layers 122 to physically contact the surface of the outermost layer of the patterned conductive layers 124 exposed by the openings. Through the interconnect structure 120, the conductive vias 140 are electrically connected to the active components and/or passive components included in the semiconductor substrate 110. In some embodiments, the conductive vias 140 in physical contact with the interconnect structure 120 are extended away from the outermost surface S130a of the passivation layer 130. For simplification, only two conductive vias 140 are presented in FIG. 3 in the semiconductor die 10 for illustrative purposes, however it should be noted that more than two conductive vias 140 may be formed; the disclosure is not limited thereto.

In some embodiments, the conductive vias 140 are formed by photolithography, plating, photoresist stripping processes or any other suitable method. The plating process may include an electroplating plating, an electroless plating, or the like. For example, the conductive vias 140 is formed by, but not limited to, forming a mask pattern (not shown) covering the passivation layer 130 with openings (not shown) corresponding to the surface of the outermost layer of the patterned conductive layers 124 exposed by the openings O1, patterning the passivation layer 130 to form contact openings (not shown) therein for exposing the surface of the outermost layer of the patterned conductive layers 124 exposed by the openings O1, forming a metallic material filling the openings formed in the mask pattern, the contact openings formed in the passivation layer 130 and the openings O1 to form the conductive vias 140 by electroplating or deposition, and then removing the mask pattern. The passivation layer 130 may be patterned by an etching process, such a dry etching process, a wet etching process, or the combination thereof. It is noted that, for example, the contact openings formed in the passivation layer 130 and a respective one opening O1 underlying thereto are spatially communicated to each other for the formation of the conductive vias 140. The mask pattern may be removed by acceptable ashing process and/or photoresist stripping process, such as using an oxygen plasma or the like. In one embodiment, the material of the conductive vias 140 includes a metal material such as copper or copper alloys, or the like.

In some embodiments, in a vertical projection on the frontside surface S110a of the semiconductor substrate 110 along the (stacking) direction Z of the semiconductor substrate 110, the interconnect structure 120 and the passivation layer 130, the conductive vias 140 may independently be in a circle-shape, an ellipse-shape, a triangle-shape, a rectangle-shape, or the like. The shape of the conductive vias 140 is not limited in the disclosure. The shape and number of the conductive vias 140 may be designated and selected based on the demand and design layout, and may be adjusted by changing the shape and number of the contact openings formed in the passivation layer 130 and the shape and number of the openings O1.

Alternatively, the conductive vias 140 may be formed by forming a first mask pattern (not shown) covering the passivation layer 130 with openings (not shown) corresponding to the surface of the outermost layer of the patterned conductive layers 124 exposed by the openings O1, patterning the passivation layer 130 to form the contact openings (not shown) therein for exposing the surface of the outermost layer of the patterned conductive layers 124 exposed by the openings O1, removing the first mask pattern, conformally forming a metallic seed layer over the passivation layer 130, forming a second mask pattern (not shown) covering the metallic seed layer with openings (not shown) exposing the contact openings formed in the passivation layer 130 and the openings, forming a metallic material filling the openings formed in the second mask pattern, the contact openings formed in the passivation layer 130 and the openings O1 by electroplating or deposition, removing the second mask pattern, and then removing the metallic seed layer not covered by the metallic material to form the conductive vias 140.

In some embodiments, the metallic seed layer is referred to as a metal layer, which includes a single layer or a composite layer comprising a plurality of sub-layers formed of different materials. In some embodiments, the metallic seed layer includes titanium, copper, molybdenum, tungsten, titanium nitride, titanium tungsten, combinations thereof, or the like. For example, the metallic seed layer may include a titanium layer and a copper layer over the titanium layer. The metallic seed layer may be formed using, for example, sputtering, PVD or the like.

In some embodiments, for the semiconductor die 10, a sidewall of the semiconductor substrate 110, a sidewall of the interconnect structure 120 and a sidewall of the passivation layer 130 are substantially aligned with each other in the direction Z and together constitute a sidewall of the semiconductor die 10. For example, illustrated outermost surface of the conductive vias 140 are protruding away from (e.g. not leveled with) the outermost surface S130a of the passivation layer 130, as shown in FIG. 3. Alternatively, illustrated outermost surface of the conductive vias 140 may be substantially leveled to and substantially coplanar with (e.g. leveled with) the outermost surface S130a of the passivation layer 130.

It is appreciated that, in some embodiments, the semiconductor die 10 described herein may be referred to as a semiconductor chip or an integrated circuit (IC). In some embodiments, the semiconductor die 10 is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), a system-on-integrated-circuit (SoIC), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor die 10 may be or include a digital chip, an analog chip or a mixed signal chip. The semiconductor die 10 may be a chip or an IC of combination-type, such as a WiFi chip simultaneously including both of a RF chip and a digital chip.

In alternative embodiments, the semiconductor die 10 is an artificial intelligence (AI) engine such as an AI accelerator; a computing system such as an AI server, a high-performance computing (HPC) system, a high power computing device, a cloud computing system, a networking system, an edge computing system, an immersive memory computing system (ImMC), a SoIC system, etc.; a combination thereof; or the like. In other alternative embodiments, the semiconductor die 10 is an electrical and/or optical input/output (I/O) interface die, an integrated passives (IPD) die, a voltage regulator (VR) die, a local silicon interconnect (LSI) die with or without deep trench capacitor (DTC) features, a local silicon interconnect die with multi-tier functions such as electrical and/or optical network circuit interfaces, IPD, VR, DTC, or the like. The type of the semiconductor die 10 may be selected and designated based on the demand and design requirement, and thus is not specifically limited in the disclosure.

In some embodiments, the semiconductor die 20 include a base die 210, a plurality of stacking dies 220 stacked on the base die 210, an insulating encapsulation 230 covering the stacking dies 220 and the base die 210, and a plurality of conductive vias 240 disposed on the base die 210. The stacking dies 220 are stacked on an illustrated top surface (e.g., a non-active surface or a backside) of the base die 210 along the direction Z, and are electrically coupled to and electrically communicated to the base die 210, for example. The base die 210 and the stacking dies 220 may together constitute an die stack having one base tier and four inner tiers as shown in FIG. 3, where the base die 210 may be referred to as a (carrier) die of the base tier in the die stack, and the stacking dies 220 may be independently referred to as a die of one inner tier in the die stack. The number of the base die 210 in the base tier and the number of the stacking dies 220 in each inner tier may not be limited to the drawings of the disclosure, and may be one or more than one, based on the demand and design requirement.

It is noted that, each of the base die 210 and the stacking dies 220 may independently include a semiconductor substrate (not shown), an interconnect structure (not shown) disposed on the semiconductor substrate, a plurality of conductive pads (not shown) disposed on and electrically connected to the interconnect structure, a passivation layer (not shown) disposed on the interconnect structure and partially exposing the conductive pads, a plurality of conductive vias (not shown) disposed on and electrically connected to the conductive pads, and/or a post-passivation layer (not shown) disposed on the passivation layer and laterally wrapping the conductive vias.

The base die 210 described herein may be referred as a semiconductor chip or an integrated circuit (IC). In some embodiments, the base die 210 includes a digital chip, an analog chip or a mixed signal chip. For example, the base die 210 is an ASIC chip, a sensor chip, a wireless and RF chip, a logic chip, or a voltage regulator chip. In some embodiments, each of the stacking dies 220 includes a memory die (e.g., a dynamic random-access memory (DRAM) die, static random-access memory (SRAM) die, a synchronous dynamic random-access memory (SDRAM), a resistive random-access memory (RRAM) die, a magnetoresistive random-access memory (MRAM) die, a NAND flash, a wide I/O memory (WIO) die, a high bandwidth memory (HBM) die, the like, etc.) with or without a controller. For example, the stacking dies 220 included in the die stack of each semiconductor die 20 are memory dies, and the base die 210 Included in the die stack of each semiconductor die 20 is a logic die providing control functionality for these memory dies, as shown in FIG. 3. In the case, the semiconductor die 20 may be a hybrid memory cube (HMC) module, a high bandwidth memory (HBM) module, or the like.

If considering multiple semiconductor dies 10 are included in the section G10, the types, sizes and shapes of some of the semiconductor dies 10 may be independently different from the types, sizes and shapes of some other of the semiconductor dies 10, in part or all; or, the types, sizes and shapes of the semiconductor dies 10 are all the same to each other, in some embodiments. If considering multiple sections G10 are adopted in one region R1, the number and positioning arrangement of the semiconductor dies 10 included in the multiple sections G10 may be different from each other, in part or all; or, the number and positioning arrangement of the semiconductor dies 10 included in the multiple sections G10 may be all the same to each other. The disclosure is not limited thereto. The disclosure is not limited thereto. If considering multiple semiconductor dies 20 are included in the section G20, the types, sizes and shapes of some of the semiconductor dies 20 may be independently different from the types, sizes and shapes of some other of the semiconductor dies 20, in part or all; or, the types, sizes and shapes of the semiconductor dies 20 are all the same to each other, in some embodiments. If considering multiple sections G20 are adopted in one region R1, the number and positioning arrangement of the semiconductor dies 20 included in the multiple sections G20 may be different from each other, in part or all; or, the number and positioning arrangement of the semiconductor dies 20 included in the multiple sections G20 may be all the same to each other. The disclosure is not limited thereto. The disclosure is not limited thereto.

The insulating encapsulation 230 laterally encapsulates the stacking dies 220 and covers the backside (e.g. the illustrated top surface) of the base die 210 exposed by the stacking dies 220 for ensuring the bonding between the base die 210 and the stacking dies 220, for example. In some embodiments, the material of the insulating encapsulation 230 includes a molding compound, a molding underfill, a resin (such as epoxy), or the like. In some alternative embodiments, the material of the insulating encapsulation 230 includes nitride such as silicon nitride, oxide such as silicon oxide, phosphosilicate glass (PSG), borosilicate glass (BSG), boron-doped phosphosilicate glass (BPSG), a combination thereof, or the like. In yet alternative embodiments, the material of each of the insulating encapsulation 230 includes an organic material (e.g., epoxy, PI, PBO, or the like), or the mixture of inorganic and organic materials (e.g., the mixture of silicon oxide and epoxy, or the like). In some embodiments, the insulating encapsulation 230 may be formed by a molding process, such as a compression molding process. In some alternative embodiments, the insulating encapsulation 230 may be formed through suitable fabrication techniques such as CVD (e.g., high-density plasma CVD (HDPCVD) or plasma-enhanced CVD (PECVD)). The insulating encapsulation 230 may be referred to as an encapsulant, a dielectric encapsulation, or an encapsulation. As illustrated in FIG. 3, for each semiconductor die 20, an illustrated top surface of the semiconductor die 20 included in a topmost tier of the die stack may be exposed by the insulating encapsulation 230. For example, the illustrated top surface of the semiconductor die 20 included in the topmost tier of the die stack is substantially leveled with and substantially coplanar to an illustrated top surface of the insulating encapsulation 230. The illustrated top surface of the semiconductor die 20 and the illustrated top surface of the insulating encapsulation 230 being substantially coplanar thereto may be referred to as a backside surface S20b of one semiconductor die 20.

The conductive vias 240 are disposed on an illustrated bottom surface (e.g., an active surface or a frontside surface) of the base die 210 along the direction Z, and are electrically coupled to and electrically communicated to the base die 210, for example. For simplification, only two conductive vias 240 are presented in FIG. 3 in each semiconductor die 20 for illustrative purposes, however it should be noted that more than two conductive vias 240 may be formed; the disclosure is not limited thereto. The formation and material of the conductive vias 240 may be similar to or substantially identical to the formation and material of the conductive vias 140 aforementioned, and thus are not repeated herein.

The semiconductor die 20 may further include an interconnect structure (not shown) disposed between and electrically connecting the base die 210 and the conductive vias 240 for providing further routing function and a passivation layer (not shown) covering the interconnect structure exposed by the conductive vias 240 for providing protection. In one example, the outermost surfaces of the conductive vias 240 may protrude away from an outermost surface of the passivation layer. However, the disclosure is not limited thereto; alternatively, the outermost surfaces of the conductive vias 240 may be substantially leveled with and coplanar to the outermost surface of the passivation layer.

As illustrated in FIG. 3, the semiconductor dies 10, 20 may be bonded to the semiconductor element 300. For example, the semiconductor dies 10, 20 are picked and placed on the semiconductor element 300, and are bonded to the semiconductor element 300 by flip-chip bonding. The semiconductor die 10 is bonded to the semiconductor element 300 by connecting the conductive vias 140 and some of the solder regions 3602 within the section G10, and the semiconductor die 20 is bonded to the semiconductor element 300 by connecting the conductive vias 240 and some of the solder regions 3602 within the section G20, for example. In some embodiments, the semiconductor die 10 and the semiconductor die 20 are electrically coupled and electrically communicated to each other through the semiconductor element 300.

Referring to FIG. 5 and FIG. 6, in some embodiments, an underfill 602 at least fills the gaps between the semiconductor die 10 and the semiconductor element 300 (e.g. the redistribution circuit structure 340) and between the semiconductor die 20 and the semiconductor element 300 (e.g. the redistribution circuit structure 340), and wraps sidewalls of the conductive vias 140, the conductive vias 240, the connecting pads 3502 and the solder regions 3602. In one embodiment, the underfill 602 filled in the gaps between the semiconductor dies 10, 20 and the redistribution circuit structure 340 are not connected to one another, as shown in FIG. 5; the disclosure is not limited thereto. Alternatively, the underfill 602 filled in the gaps between the semiconductor dies 10, 20 and the redistribution circuit structure 340 may be connected to one another. In one embodiment, a sidewall of the semiconductor die 10 and a sidewall of the semiconductor die 20 are free of the underfill 602, as shown in FIG. 5; the disclosure is not limited thereto. Alternatively, the sidewall of the semiconductor die 10 and the sidewall of the semiconductor die 20 may be covered by the underfill 602. The underfill 602 may be any acceptable material, such as a polymer, epoxy resin, molding underfill, or the like, for example. The underfill 602 may be formed by underfill dispensing, a capillary flow process, or any other suitable method. Owing to the underfill 602, the bonding strength between the semiconductor dies 10, 20 and the semiconductor element 300 is enhanced. However, the disclosure is not limited thereto; alternatively, the underfill 602 may be optionally omitted.

Continued on FIG. 5 and FIG. 6, in some embodiments, after forming the underfill 602, an encapsulant 400 is formed over the semiconductor element 300 to cover the semiconductor dies 10, 20, the underfill 602, the solder regions 3604, the connecting pads 3504 and the semiconductor element 300 exposed therefrom. For example, the encapsulant 400 at least fills up the gaps between the semiconductor dies 10, 20, between the underfill 602 respectively underlying the semiconductor dies 10, 20, between the connecting pads 3504, and between the solder regions 3604. In some embodiments, the semiconductor dies 10, 20, the underfill 602, the solder regions 3604, the connecting pads 3504 are surrounded and covered by the encapsulant 400. As shown in FIG. 5, the backside surface S110b (e.g. the non-active surface) of the semiconductor die 10 and the backside surface S20b (e.g. the non-active surfaces) of the semiconductor die 20 may be substantially leveled with and substantially coplanar to an illustrated top surface S400t of the encapsulant 400. In the case, the semiconductor dies 10, 20 are laterally encapsulated by the encapsulant 400, and the underfill 602, the connecting pads 3504 and the solder regions 3604 are embedded in the encapsulant 400.

However, the disclosure is not limited thereto; alternatively, the semiconductor dies 10, 20, the underfill 602, the connecting pads 3504 and the solder regions 3604 are embedded in the encapsulant 400. That is, the backside surface S110b of the semiconductor die 10 and the backside surface S20b of the semiconductor die 20 may be embedded in the encapsulant 400 (e.g. not revealed by the substantially flat and planar illustrated top surface S400t of the encapsulant 400).

In some embodiments, the encapsulant 400 is a molding compound formed by a molding process. In some embodiments, the encapsulant 400 include polymers (such as epoxy resins, phenolic resins, silicon-containing resins, or other suitable resins), dielectric materials, or other suitable materials. In an alternative embodiment, the encapsulant 400 may include an acceptable insulating encapsulation material. The encapsulant 400 may further include inorganic filler or inorganic compound (e.g. silica, clay, and so on) which can be added therein to optimize coefficient of thermal expansion (CTE) of the encapsulant 400, the disclosure is not limited thereto. The encapsulant 400 may be referred to as an insulating encapsulation, a dielectric encapsulation, or an encapsulation. For example, the encapsulant 400 is formed by, but not limited to, over-molding the semiconductor dies 10, 20 by an insulating encapsulation material, and patterning the insulating encapsulation material to form the encapsulant 400. The insulating encapsulation material may be patterned by a planarizing process until the semiconductor dies 10 and 20 are accessibly exposed by the encapsulant 400. Owing to the encapsulant 400, the bonding strength between the semiconductor dies 10, 20 and the semiconductor element 300 is further enhanced, and the semiconductor dies 10, 20 are protected from the damages caused by the external contacts.

During the planarizing process, the semiconductor dies 10, 20 independently may also be planarized. The planarizing process is performed by mechanical grinding, CMP, etching or combinations thereof, for example. The etching may include dry etching, wet etching, or a combination thereof. After the planarizing process, a cleaning process may be optionally performed to clean and remove the residue generated from the planarizing process. However, the disclosure is not limited thereto, and the planarizing process may be performed through any other suitable method.

Referring to FIG. 7, in some embodiments, a plurality of conductive terminals 380 are disposed on the semiconductor element 300 to electrically connect thereto. In some embodiments, before disposing the conductive terminals 380 over the surface S310b of the substrate 310, the structure depicted in FIG. 5 is flipped (e.g., turned upside down) and placed onto a temporary carrier (not shown), where the backside surface S110b of the semiconductor die 10, the backside surface S20b of the semiconductor die 20 and the illustrated top surface S400t of the encapsulant 400 are covered by the temporary carrier, the surface S310b is facing upwards and accessibly revealed, and the substrate 310 is thinned down until the surface S310b accessibly reveals the through vias 320. In other words, after thinning process, the through vias 320 penetrate through the substrate 310, where the through vias 320 extend from the surface S310a toward the surface S310b. In some embodiments, the through vias 320 are sometimes referred to as through-substrate-vias or through-silicon-vias (TSV) as the substrate 310 is a silicon substrate. The surface S310b may be referred to as a backside surface (or a back side) of the substrate 310. The conductive terminals 380 includes micro-bumps, metal pillars, controlled collapse chip connection (C4) bumps (for example, which may have, but not limited to, a size of about 80 μm), a ball grid array (BGA) bumps (for example, which may have, but not limited to, a size of about 400 μm), electroless nickel-immersion gold technique (ENIG) formed bumps, electroless nickel-electroless palladium-immersion gold technique (ENEPIG) formed bumps, or the like, in some embodiments.

The thinning process may include a mechanical grinding process, a CMP process, an etching process, or combinations thereof. The etching process may include a dry etching, a wet etching, or a combination thereof. During the thinning process, the through vias 320 may also be removed, partially. After the thinning process, a cleaning process may be optionally performed to clean and remove the residue generated from the thinning process. However, the disclosure is not limited thereto, and the thinning process may be performed through any other suitable method.

In some embodiments, after the through vias 320 are accessibly revealed by the substrate 310, the conductive terminals 380 are disposed over the substrate 310 by connecting the through vias 320. For example, as shown in FIG. 7, the conductive terminals 380 are electrically coupled to the through vias 320 through direct contacts. In some embodiments, some of the conductive terminals 380 are electrically coupled to the semiconductor die 10 through some of the through vias 320, the redistribution circuit structure 340, and the connecting pads 3502 and the solder regions 3602 within the section G1. In some embodiments, some of the conductive terminals 380 are electrically coupled to the semiconductor die 20 through some of the through vias 320, the redistribution circuit structure 340, and the connecting pads 3502 and the solder regions 3602 within the section G20. In some embodiments, some of the conductive terminals 380 are electrically coupled to the connecting pads 3502 and the solder regions 3602 within the section G70 through some of the through vias 320 and the redistribution circuit structure 340. In some embodiments, some of the conductive terminals 380 are electrically coupled to the active components and/or passive components (if any) in the substrate 310 through some of the through vias 320 and the redistribution circuit structure 340.

Alternatively, prior to disposing the conductive terminals 380 over the substrate 310, an additional redistribution circuit structure (not shown) may be formed on the surface S310b exposing the through vias 320 and to be electrically connected to the through vias 320, for providing routing functionality. The formation and material of the additional redistribution circuit structure may be substantially identical or similar to the forming process and material of the redistribution circuit structure 340 as discussed in FIG. 1, and thus are not repeated herein for brevity. That is to say, the conductive terminals 380 are disposed over the substrate 310 by connecting the additional redistribution circuit structure (e.g., at least metal/conductive features thereof). In such alternative embodiments, the conductive terminals 380 are electrically coupled to the through vias 320 through the additional redistribution circuit structure. In some embodiments, some of the conductive terminals 380 are electrically coupled to the semiconductor die 10 through the additional redistribution circuit structure, some of the through vias 320, the redistribution circuit structure 340, and the connecting pads 3502 and the solder regions 3602 within the section G1. In some embodiments, some of the conductive terminals 380 are electrically coupled to the semiconductor die 20 through the additional redistribution circuit structure, some of the through vias 320, the redistribution circuit structure 340, and the connecting pads 3502 and the solder regions 3602 within the section G20. In some embodiments, some of the conductive terminals 380 are electrically coupled to the connecting pads 3502 and the solder regions 3602 within the section G70 through the additional redistribution circuit structure, some of the through vias 320 and the redistribution circuit structure 340. In some embodiments, some of the conductive terminals 380 are electrically coupled to the active components and/or passive components (if any) in the substrate 310 through the additional redistribution circuit structure, some of the through vias 320 and the redistribution circuit structure 340.

After disposing the conductive terminals 380 over the substrate 310, the temporary carrier is debonded and removed from the backside surface S110b of the semiconductor die 10, the backside surface S20b of the semiconductor die 20 and the illustrated top surface S400t of the encapsulant 400. Prior to debonding the temporary carrier, a holding device 50 is adopted to secure the semiconductor element 300 by holding the conductive terminals 380. For example, the holding device 50 may be an adhesive tape, a carrier film, or a suction pad.

Referring to FIG. 8 and FIG. 9, in some embodiments, the encapsulant 400 is patterned (or trimmed) to form a plurality of openings O2 in the encapsulant 400 within the sections G70 of the regions R1. Through the openings O2 formed in the encapsulant 400, the solder regions 3604 within the sections G70 of the regions R1 can be accessibly revealed by the encapsulant 400, thereby facilitating the placement of optical die(s) in a subsequent step(s). In some embodiments, the encapsulant 400 is patterned by performing a cutting process C1 on the encapsulant 400 over the semiconductor element 300 until the solder regions 3604 (e.g., in the sections G70 of the regions R1) are exposed by the openings O2 formed in the encapsulant 400. That is to say, the cutting process C1 is a contact cutting process, for example. In some embodiments, the cutting process C1 is performed by a mechanical cutting process (such as blade sawing) with a blade 60, where the blade 60 includes a blade body 62 and a plurality of diamond particles 64 distributed over an outer surface of the blade body 62, and the outer surface of the blade body 62 is configured to be in contact with the object to-be-cut during the cutting process C1. The blade body 62 may have a blade width W62 approximately ranging from 2000 μm to 3000 μm, although other suitable blade width may alternatively be utilized. For example, as shown in FIG. 8, a thickness T400 of the encapsulant 400 remaining in the sections G70 of the regions R1 is approximately ranging from 10 μm to 20 μm, although other suitable thickness may alternatively be utilized.

Referring to FIG. 10 in conjunction with FIG. 8 and FIG. 9, in some embodiments, certain structural features including the encapsulant 400, the solder regions 3604 and the connecting pads 3504 indicated by the dashed-box B depicted in FIG. 8 are stressed for illustration purposes. As shown in FIG. 8 and FIG. 10, the opening O2 may partially penetrate through the encapsulant 400 in the direction Z, and further extend from an edge E400 of the encapsulant 400 to an edge (not labeled, away from the edge E400) of the section G70 in the direction X. For example, the opening O2 has a vertical side S1, a horizontal side S2 and a curved surface S3 connecting the vertical side S1 and the horizontal side S2, where the curved surface S3 is a concave curved surface as shown in FIG. 10. The curved surface S3 may have a curvature approximately ranging from 0.01 to 0.2, although other suitable curvature may alternatively be utilized. In addition, in the cross-section along the direction Z, the curved surface S3 includes a vertical dimension DO1 as measured in the direction Z approximately ranging from 5 μm to 100 μm and a horizontal dimension D02 as measured in the direction X (or Y) approximately ranging from 5 μm to 100 μm, although other suitable vertical dimension and/or horizontal dimension may alternatively be utilized. In addition, after the cutting process C1, the curved surface S3 may have a predetermined surface roughness (Ra) of approximately ranging from 0.1 μm to 10 μm, although other suitable surface roughness may alternatively be utilized. The vertical surface S1 may be considered as the edge of the section G70, sometimes. On the other hand, the horizontal surface S2 includes an illustrated top surface S400 of the encapsulant 400 remaining in the opening O2 and illustrated top surfaces S3604 of the solder regions 3604, for example, as shown in FIG. 10. After the cutting process C1, for the horizontal surface S2, the illustrated top surface S400 of the encapsulant 400 may have a predetermined surface roughness (Ra) of approximately ranging from 0.1 μm to 10 μm, and the illustrated top surfaces S3604 of the solder regions 3604 may have a predetermined surface roughness (Ra) of approximately ranging from 0.1 μm to 5 μm, although other suitable surface roughness may alternatively be utilized; also see FIG. 11 through FIG. 14. In some embodiments, the surface roughness ‘Ra’ is calculated by an average of the vertical distances from highest peaks to lowest valleys of micro structures at a sampling surface. In some embodiments, the surface roughness of the illustrated top surface S400 of the encapsulant 400 is greater than a surface roughness of the illustrated top surface S400t of the encapsulant 400. That is to say, a portion of the encapsulant 400 located inside the openings O2 has a surface roughness greater than a surface roughness of a portion of the encapsulant 400 located outside the openings O2.

Referring to FIG. 11 through FIG. 14 in conjunction with FIG. 10, in some embodiments, certain structural features including the encapsulant 400 and the solder regions 3604 indicated by the dashed-box D depicted in FIG. 10 are stressed for illustration purposes, where the enlarged cross-sectional views shown in the dashed-box D1 of FIG. 11, the dashed-box D2 of FIG. 12, the dashed-box D3 of FIG. 13 and the dashed-box D4 of FIG. 14 are the various embodiments of the cross-sectional view of the dashed-box D depicted in FIG. 10. However, the disclosure is not limited thereto. In some embodiments, for each opening O2, the cutting process C1 includes one or more cutting steps, where the cutting steps each may be, based on the sequential orders, respectively referred to a first cut, a second cut, a third cut, a fourth cut, and so on. The disclosure does not limit the number of the cutting steps included in the cutting process C1, which can be selected based on the demand and design requirement.

For a non-limiting example, as shown in FIG. 10 and FIG. 11, the cutting process C1 may include five cuts, such as a first cut CS1, a second cut CS2, a third cut CS3, a fourth cut CS4 and a fifth cut CS5, where a cutting track of each cut may overlap with a cutting track of another cut (e.g., performed immediately before or right after) with a distance D03, where the distance DO3 is greater than zero and less than the blade width W62. Alternatively, the first cut CS1, the second cut CS2, the third cut CS3, the fourth cut CS4 and the fifth cut CS5 may be performed immediately one after one without an overlapped distance with others in their cutting tracks (e.g., the distance DO3 is zero), with a distance between their cutting tracks being zero. Or alternatively, the cutting process C1 may include a single one cut, as long as the blade width is large enough to form the opening O2 in one single step.

On the other hand, as shown in FIG. 11, the first cut CS1, the second cut CS2, the third cut CS3, the fourth cut CS4 and the fifth cut CS5 share a common cutting depth, where topmost points of the encapsulant 400 and/or the solder regions 3604 (resulted in each cut C1-C5) are disposed at the same plane P1. Alternatively, the first cut CS1, the second cut CS2, the third cut CS3, the fourth cut CS4 and the fifth cut CS5 may not share common cutting depth, where topmost points of the encapsulant 400 and/or the solder regions 3604 (resulted in each cut C1-C5) are respectively disposed at the different planes. For an non-limiting example, as shown in FIG. 12, the first cut CS1, the second cut CS2, the third cut CS3, the fourth cut CS4 and the fifth cut CS5 share three common cutting depth, where topmost points of the encapsulant 400 and/or the solder regions 3604 (resulted in each cut C1-C5) are disposed at the different planes P2, P3 and P4. The disclosure is not limited thereto, cutting depths of the cuts may all be different from each other.

Furthermore, a reflow process may be performed on the structure of FIG. 11 and/or the structure of FIG. 12 to re-shape the solder regions 3604, where the uneven topmost surfaces S3604 (with the surface roughness ‘Ra’) of the solder regions 3604 exposed by the opening O2 due to the cutting process C1 may be removed, see FIG. 13 and FIG. 14. For example, after reflowing, the topmost surfaces S3604 of the solder regions 3604 exposed by the opening O2 each include a smoothly curved surface, e.g., a convex surface as shown in FIG. 13 and FIG. 14.

Back to FIG. 8, after patterning the encapsulant 400, a dicing (or singulation) process is process to cut through the encapsulant 400 and the semiconductor element 300 to form a plurality of separate and individual chip-on-wafer (CoW) structures 80. The CoW structures 80 may be referred to as CoW packages. The dicing (or singulation) process may be or include a wafer dicing process. The conductive terminals 380 may be referred to as conductive connectors or input/output (I/O) terminals of each CoW structure 80. It is appreciated that FIG. 9 is a schematic plane view before dicing.

Referring to FIG. 15 and FIG. 16, in some embodiments, at least one CoW structure 80 is placed over and bonded to the substrate 500 through the conductive terminals 380. For illustration purpose, only one CoW structure 80 is shown in FIG. 15 and FIG. 16, however the disclose is not limited thereto. The number of the CoW structure 80 to be disposed on and electrically coupled to the substrate 500 may be one, two, three or more, depending on the demand and design layout. Up to here, a semiconductor package 1000 with a chip-on-wafer-on-substrate (CoWoS) structure is manufactured. The semiconductor package 1000 may be referred to as a CoWoS package.

The substrate 500 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. In some alternative embodiments, the substrate 500 is a SOI substrate, where the SOI substrate may include a layer of a semiconductor material such as epitaxial silicon, germanium, silicon germanium, SOI, silicon germanium on insulator (SGOI), or combinations thereof. In further alternative embodiments, the substrate 500 is based on an insulating core, such as a fiberglass reinforced resin core. One example core material is fiberglass resin such as flame retardant class 4 (FR4). Alternatives for the core material may include bismaleimide triazine (BT) resin, or alternatively, other printed circuit board (PCB) materials or films. In yet further alternative embodiments, the substrate 500 is a build-up film such as Ajinomoto build-up film (ABF) or other suitable laminates.

In one embodiment, the substrate 500 may include active and/or passive components (not shown), such as transistors, capacitors, resistors, combinations thereof, or the like which may be used to generate the structural and functional requirements of the design for the semiconductor package. The active and/or passive components may be formed using any suitable methods. However, the disclosure is not limited thereto; in an alternative embodiment, the substrate 500 may be substantially free of active and/or passive components.

In some embodiments, the substrate 500 includes a plurality of bonding pads 510, a plurality of bonding pads 520, a plurality of metallization layers 530 and a plurality of vias (not shown) interconnected therebetween, where the bonding pads 510, 520 connected to the metallization layers 530 and vias. The metallization layers 530 and the vias together form a functional circuitry providing routing for the substrate 500. The metallization layers 530 and the vias embedded in the substrate 500 may be formed of alternating layers of dielectric (e.g., low-k dielectric material) and conductive material (e.g., copper), with the vias interconnecting the layers of conductive material; and may be formed through any suitable process (such as deposition, damascene, dual damascene, or the like). The bonding pads 510, 520 are used to provide electrical connection with external component(s) for the substrate 500. In some embodiments, the bonding pads 510, 520 are located at two opposite sides of the substrate 500 along the direction Z and electrically connected to each other through the metallization layers 530 and the vias. As shown in FIG. 15, for example, the conductive terminals 380 of the CoW structure 80 are connected to the bonding pads 510 of the substrate 500, respectively. As shown in FIG. 15, in some embodiments, through bonding pads 510 and the conductive terminals 380, the CoW structure 80 is electrically connected to the substrate 500. In addition, the substrate 500 is considered as a circuit structure (e.g. an organic substrate with circuitry structure embedded therein, such as printed circuit board (PCB)).

In some embodiments, a plurality of conductive terminals 540 may be optionally disposed on a bottom surface of substrate 500, as shown in FIG. 15. The conductive terminals 540 may be used to physically and electrically connect the substrate 500 to other devices, packages, connecting components, and the like. The conductive terminals 540 are referred to as conductive conductors or I/O terminals of the substrate 500 for providing physical and/or electrical connection to external components, in the disclosure. The conductive terminals 540 includes micro-bumps, metal pillars, controlled collapse chip connection (C4) bumps (for example, which may have, but not limited to, a size of about 80 μm), a ball grid array (BGA) bumps (for example, which may have, but not limited to, a size of about 400 μm), electroless nickel-immersion gold technique (ENIG) formed bumps, electroless nickel-electroless palladium-immersion gold technique (ENEPIG) formed bumps, or the like, in some embodiments. As shown in FIG. 15, the conductive terminals 540 and the CoW structure 80 are respectively located on two opposite sides of the substrate 500 in the direction Z, where some of the conductive terminals 540 are electrically connected to the CoW structure 80 through the bonding pads 520, the metallization layers 530, the vias, the bonding pads 510 and the conductive terminals 380, for example.

In some embodiments, one or more surface devices (not shown) may be optionally connected to the substrate 500. The surface devices may be, for example, used to provide additional functionality or programming to the CoW structure 80. The surface devices may include surface mount devices (SMDs) or an integrated passive devices (IPDs) that comprise passive devices such as resistors, inductors, capacitors, jumpers, combinations of these, or the like that are desired to be connected to and utilized in conjunction with the CoW structure 80. The surface devices may be disposed at one side or two opposite sides of the substrate in the direction Z. The number of the surface devices are not limited, and may be selected based on the demand and design layout. The disclosure is not limited thereto. For example, the surface devices are electrically connected to the CoW structure 80 through the substrate 500.

In some embodiments, an underfill 604 is formed on the substrate 500. As shown in FIG. 15, for example, the underfill 604 fills the gap between the CoW structure 80 and the substrate 500, and wraps sidewalls of the conductive terminals 380. Owing to the underfill 604, the bonding strength between the CoW structure 80 and the substrate 500 is enhanced. The material and formation of the underfill 604 may be the same or similar to the material and formation of underfill 602 as described in FIG. 5 and FIG. 6, and thus are not repeated herein for simplicity. However, the disclosure is not limited thereto; alternatively, the underfill 604 may be optionally omitted.

Referring to FIG. 17 and FIG. 18, in some embodiments, at least one optical die (or component/package) 70 is disposed over the substrate 310 of the semiconductor element 300 within the section G70 of region R1. Only one optical die 70 in the section G70 of the region R1 is shown in FIG. 17 and FIG. 18 for illustrative purpose and simplicity. Indeed, the number of the optical die 70 in each section G70 may be one, two, three or more, the disclosure is not limited thereto. If considering multiple optical dies 70 are included in the section G70, the types, sizes and shapes of some of the optical dies 70 may be independently different from the types, sizes and shapes of some other of the optical dies 70, in part or all; or, the types, sizes and shapes of the optical dies 70 are all the same to each other, in some embodiments. If considering multiple sections G70 are adopted in one region R1, the number and positioning arrangement of the optical dies 70 included in the multiple sections G70 may be different from each other, in part or all; or, the number and positioning arrangement of the optical dies 70 included in the multiple sections G70 may be all the same to each other. The disclosure is not limited thereto.

In some embodiments, the optical die 70 includes a semiconductor substrate 710, a interconnect structure 720 disposed over the semiconductor substrate 710, one or more optoelectronic devices 730 disposed in/on the semiconductor substrate 710 and/or disposed in/on the interconnect structure 720, and a plurality of conductive vias 740 disposed on and electrically coupled to the interconnect structure 720. The semiconductor substrate 710 may be a semiconductor substrate such as a silicon substrate. Alternatively, the semiconductor substrate 710 may be a transparent semiconductor substrate. The interconnect structure 720 may include a plurality of dielectric layers, and a plurality of metal lines and a plurality of vias in the plurality of dielectric layers. The one or more optoelectronic devices 730 in accordance with the disclosure can take any number of forms, including waveguides (e.g., silicon type or non-silicon type), splitters, modulators, demodulators, couplers, de-couplers, multiplexers, de-multiplexers, transmitters, receivers, and a host of other applications. In addition, the optoelectronic device 730 includes a series of optical paths included in a waveguide. At various locations, the optical paths may run in parallel with one another, may branch apart from one another, or may merge with one another to facilitate desired functionality (e.g., optical signal transmissions). The disclosure is not limited thereto.

The details of the conductive vias 740 are substantially identical to or similar to the details of the conductive vias 140 and/or the conductive vias 240 as discussed in FIG. 3 and FIG. 4, and thus are not repeated herein for brevity. The conductive vias 740 may be referred to as conductive terminals or conductive connectors of the optical die 70. In some embodiments, the conductive vias 740 are electrically coupled to the one or more optoelectronic devices 730 through the interconnect structure 720, with electrical signal transmissions. In some embodiments, the optical die 70 further includes a plurality of solder regions 750 disposed on and electrically coupled to the conductive vias 740. The solder is or include either eutectic solder or non-eutectic solder. The solder may include lead or be lead-free, and may include Sn—Ag, Sn—Cu, Sn—Ag—Cu, or the like. The solder regions 750 may be omitted, alternatively.

The optical die 70 may further include one or more optical-lens structures (not shown) on a side of the semiconductor substrate 710 opposing to the interconnect structure 720, where the one or more optical-lens structures may optical couple to the optoelectronic device 730. In such case, the one or more optical-lens structures may be posited at an optical path between the one or more optoelectronic devices 730 and an external device optically coupled to the one or more optoelectronic devices 730. The disclosure is not limited thereto. The optical die 70 may or may not include photo diodes and/or electrical devices such as controllers, integrated circuits, drivers, amplifiers, the like, or combinations thereof.

Continued on FIG. 17 and FIG. 18, the optical die 70 is picked and placed over the semiconductor element 300 within the section G70 of the region R1, where the optical die 70 is bonded to the solder regions 3604 by flip-chip bonding. In some embodiments, the optical die 70 is bonded to the semiconductor element 300 by connecting the conductive vias 740 and some of the solder regions 3604 within the section G70. In some embodiments, the optical die 70 is electrically coupled and electrically communicated to the semiconductor dies 10 and/or 20 through the semiconductor element 300. With the optical die 70, the semiconductor package 1000 may be referred to as a CoWoS structure or a CoWoS package integrated with an optical die.

Referring to FIG. 19 in conjunction with FIG. 17 and FIG. 18, in some embodiments, certain structural features including an underfill 606, a part of the optical die 70 (including the conductive vias 740 and the solder regions 750), the encapsulant 400, the solder regions 3604 and the connecting pads 3504 indicated by the dashed-box C depicted in FIG. 17 are stressed for illustration purposes. As shown in FIG. 17 and FIG. 19, after the bonding process, the solder regions 750 are in physical contact with the solder regions 3604, thereby establishing electrical connections between the optical die 70 and the semiconductor element 300, for example. In some embodiments, the bonding process may include a reflow process. In some embodiments, during the bonding process, the reflow process is performed by heating the solder regions 750 of the optical die 70 and the solder regions 3604 of the semiconductor element 300 to a suitable temperature for bonding. For example, during the reflow process, the temperature gradually increases until it reaches the melting temperature of the solder regions 750, 3604. During the bonding process, the solder regions 750, 3604 may be heated to a temperature of or greater than a melting point thereof. For example, the temperature is elevated about 20° C. above the melting temperature of the solder regions 750, 3604. It is noted that the reflowed temperature may vary depending on the composition content of each of the solder regions 750, 3604. In some embodiments, after the reflowing process, a proper contact (e.g., physical and electrical connections) is established between the solder regions 750 and the solder regions 3604, the solder regions 750 are disposed between and physical connecting the conductive vias 740 and the solder regions 3604.

Referring to FIG. 20 through FIG. 21 in conjunction with FIG. 19, in some embodiments, certain structural features including a part of the underfill 606, the conductive vias 740, the solder regions 750, the encapsulant 400, the solder regions 3604 indicated by the dashed-box E depicted in FIG. 19 are stressed for illustration purposes, where the enlarged cross-sectional views shown in the dashed-box E1 of FIG. 20 and the dashed-box E2 of FIG. 21 are the various embodiments of the cross-sectional view of the dashed-box E depicted in FIG. 19. However, the disclosure is not limited thereto. In the embodiments of which the enlarged cross-sectional views shown in the dashed-box D1 of FIG. 11 or the dashed-box D3 of FIG. 13 is adopted, the illustrated top surface S400 of the encapsulant 400 remaining in the opening O2 still maintains the same topography (e.g., the predetermined surface roughness (Ra) and the plane P1) as discussed previously, after bonding the optical die 70 onto the semiconductor element 300 by flip-chip process, see FIG. 20. In the embodiments of which the enlarged cross-sectional views shown in the dashed-box D2 of FIG. 12 or the dashed-box D4 of FIG. 14 is adopted, the illustrated top surface S400 of the encapsulant 400 remaining in the opening O2 still maintains the same topography (e.g., the predetermined surface roughness (Ra) and the planes P2-P4) as discussed previously, after bonding the optical die 70 onto the semiconductor element 300 by flip-chip process, see FIG. 21. Although clear interfaces between the solder regions 750 and the solder regions 3604 are shown in FIG. 17 and FIGS. 19-21, the clear interfaces may not presented if the solder regions 750 and the solder regions 3604 being made of same material and bonded to each other under a proper reflowed temperature.

Back to FIG. 17 and FIG. 18, in some embodiments, an underfill 606 at least fills the gaps between the optical die 70 and the semiconductor element 300 (e.g. the redistribution circuit structure 340), and wraps sidewalls of the conductive vias 740 (also see FIG. 19 through FIG. 21). In FIG. 17, the underfill 606 may at least stand on a portion of the horizontal surface S2 and further extends onto the curved surface S3. Alternatively, the underfill 606 may further extend onto the vertical surface S1 and/or completely cover the horizontal surface S2. The disclosure is not limited thereto. Owing to the underfill 606, the bonding strength between the optical die 70 and the semiconductor element 300 is enhanced. The material and formation of the underfill 606 may be the same or similar to the material and formation of underfill 602 as described in FIG. 5 and FIG. 6, and thus are not repeated herein for simplicity. However, the disclosure is not limited thereto; alternatively, the underfill 606 may be optionally omitted.

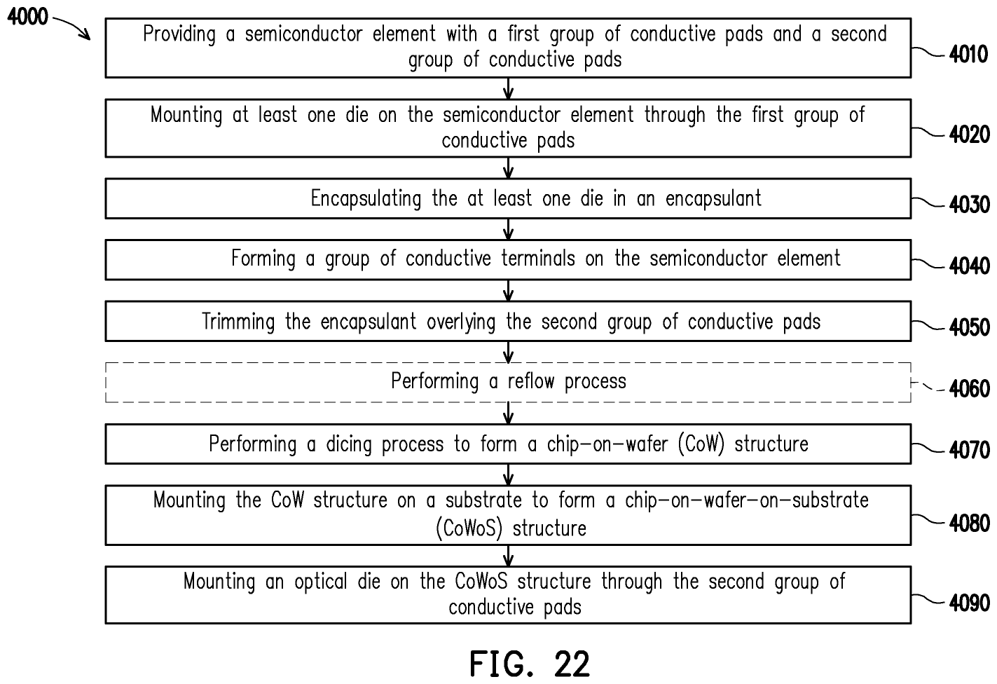

FIG. 22 is a flow chart illustrating a method of manufacturing a semiconductor package in accordance with some embodiments of the disclosure. While examples of FIG. 22 are mentioned with reference to the preceding cross-sectional views of FIG. 1 through FIG. 21, it will be appreciated that the structures shown in FIG. 1 through FIG. 21 are not limited to the method 4000 but rather may stand alone separate of the methods. Further, while method 4000 are described as a series of acts, it will be appreciated that the order of the acts (and/or portions of those acts) may be altered in other embodiments. Further still, while FIG. 22 illustrates a specific series of acts, some acts that are illustrated and/or described may be omitted in other embodiments. Further, additional acts that are not illustrated and/or described in FIG. 22 may be included in other embodiments.

At act 4010, a semiconductor element with a first group of conductive pads and a second group of conductive pads is provided. In some embodiments, act 4010 can be consistent with FIG. 1 and FIG. 2.

At act 4020, at least one die is mounted on the semiconductor element through the first group of conductive pads. In some embodiments, act 4020 can be consistent with FIG. 3 and FIG. 4.

At act 4030, the at least one die is encapsulated in an encapsulant. In some embodiments, act 4030 can be consistent with FIG. 5 and FIG. 6.

At act 4040, a group of conductive terminals are on the semiconductor element. In some embodiments, act 4040 can be consistent with FIG. 7.

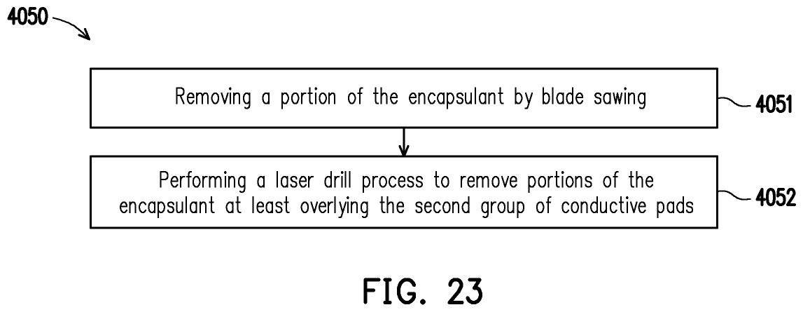

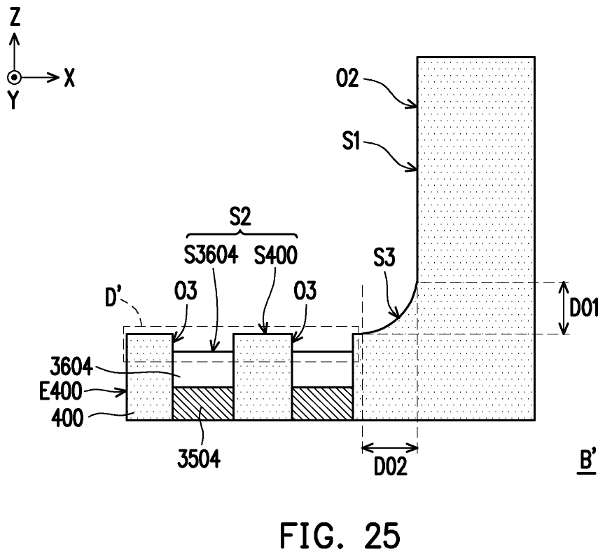

At act 4050, the encapsulant overlying the second group of conductive pads is trimmed. In some embodiments, act 4050 can be consistent with FIG. 8 and FIG. 9 in conjunction with FIG. 10 through FIG. 14. However act 4050 may be performed with FIG. 23 in conjunction with FIG. 25 through FIG. 34, which will be discussed in greater details later.

At act 4060, which is optional, a reflow process is performed. In some embodiments, act 4060 can be consistent with FIG. 13 and FIG. 14.

At act 4070, a dicing process is performed to form a CoW structure. In some embodiments, act 4070 can be consistent with FIG. 8.

At act 4080, the CoW structure is mounted on a substrate to form a CoWoS structure. In some embodiments, act 4080 can be consistent with FIG. 15 and FIG. 16.

At act 4090, an optical die is mounted on the CoWoS structure through the second group of conductive pads. In some embodiments, act 4090 can be consistent with FIG. 17 and FIG. 18 in conjunction with FIG. 19 through FIG. 21.

In some embodiments, the encapsulant overlying the second group of conductive pads is trimmed (act 4050) by performing a cutting process, see FIGS. 8-9 in conjunction with FIGS. 10-14. However, the disclosure is not limited thereto; alternatively, the encapsulant overlying the second group of conductive pads is trimmed (act 4050) by performing a cutting process (act 4051) followed by a laser drill process (act 4052). FIG. 23 is a flow chart illustrating a part of a method of manufacturing a semiconductor package in accordance with some alternative embodiments of the disclosure. While examples of FIG. 23 combined with FIG. 22 are mentioned with reference to the preceding cross-sectional views of FIGS. 1-9, 15-18, and 24-40, it will be appreciated that the structures shown in FIGS. 1-9, 15-18, and 24-40 are not limited to the method 4000 (further involving act 4051 and act 4052) but rather may stand alone separate of the methods. Further, while method 4000 (further involving act 4051 and act 4052) are described as a series of acts, it will be appreciated that the order of the acts (and/or portions of those acts) may be altered in other embodiments. Further still, while FIG. 23 combined with FIG. 22 illustrates a specific series of acts, some acts that are illustrated and/or described may be omitted in other embodiments. Further, additional acts that are not illustrated and/or described in FIG. 23 combined with FIG. 22 may be included in other embodiments.

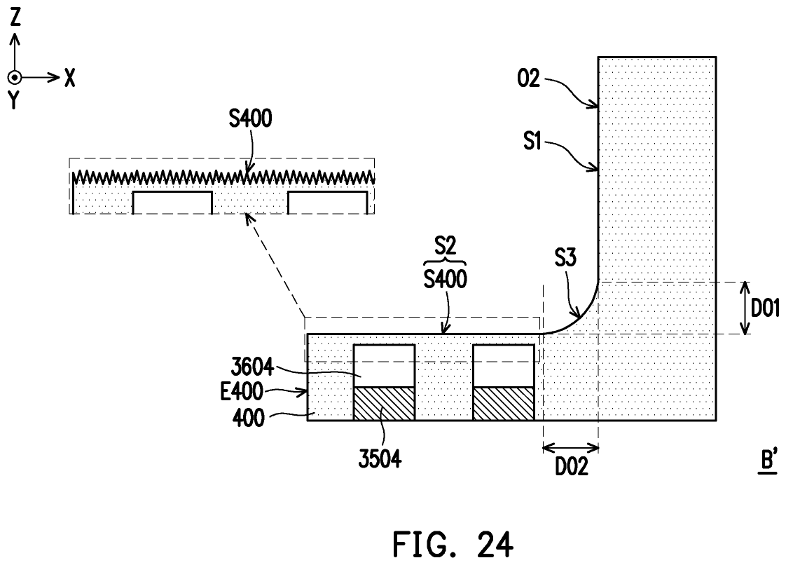

At act 4051 (which following act 4040 previously discussed), a portion of the encapsulant is removed by blade sawing. In some embodiments, act 4051 can be consistent with FIG. 8 and FIG. 9 in conjunction with FIG. 24 (which will be discussed in greater details later).

At act 4052, a laser drill is performed to remove portions of the encapsulant at least overlying the second group of conductive pads. In some embodiments, act 4052 can be consistent with FIG. 8 and FIG. 9 in conjunction with FIG. 25 through FIG. 29 (which will be discussed in greater details later) and FIG. 8 and FIG. 9 in conjunction with FIG. 30 through FIG. 34 (which will be discussed in greater details later).

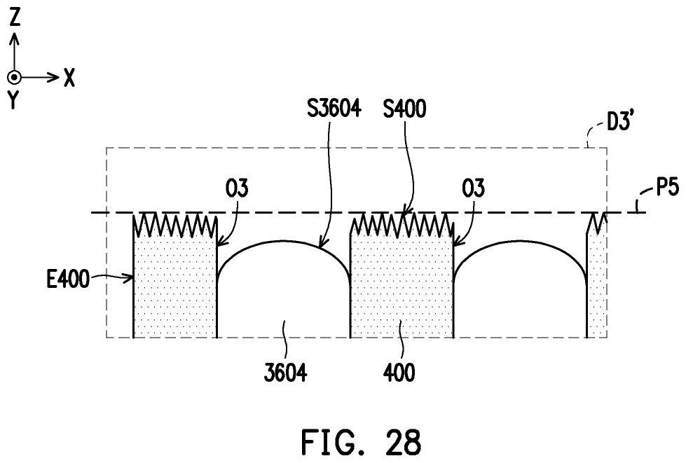

At act 4060 (which following act 4052), which is optional, a reflow process is performed. In some embodiments, act 4060 can be consistent with FIGS. 28-29 and FIGS. 33-34. Then, act 4070, act 4080 and act 4090 may be performed to manufacture a semiconductor package having a CoWoS structure integrated with an optical die, following act 4060.

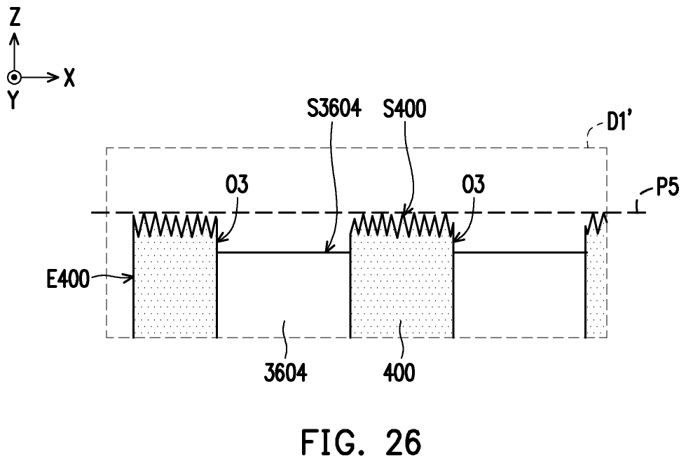

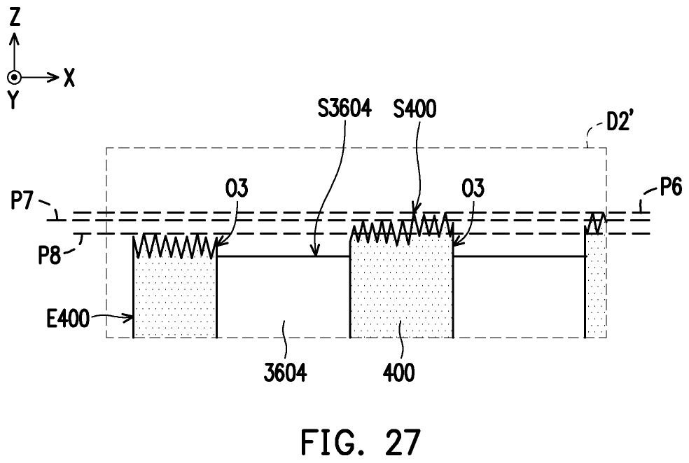

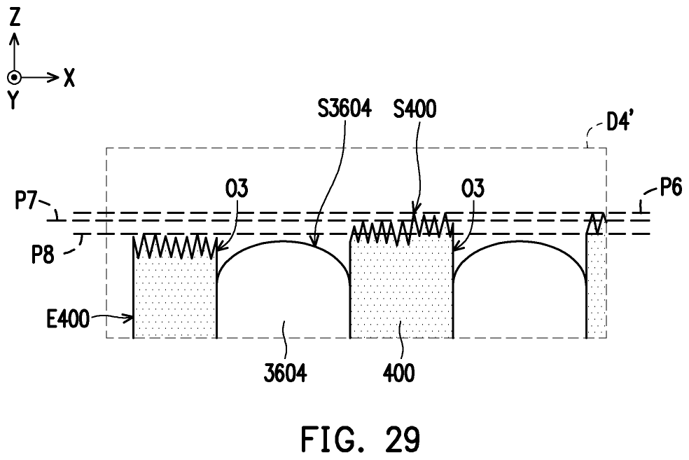

FIG. 24 through FIG. 25 are schematic cross-sectional views of various stages in a part of a manufacturing method of a semiconductor package in accordance with alternative embodiments of the disclosure, showing a cutting region which is a predetermined location of an optical die integrated with the semiconductor package, which is outlined by a dashed-box B depicted in FIG. 8 (e.g., denoted as B′ in FIG. 24 and FIG. 25). FIG. 26 through FIG. 29 are schematically enlarged, cross-sectional views showing various embodiments of an uppermost surface of an encapsulant and an uppermost surface of a solder region at the cutting region of FIG. 25, which are outlined by a dashed-box D′ depicted in FIG. 25 (e.g., a dashed-box D1′ in FIG. 26, a dashed-box D2′ in FIG. 27, a dashed-box D3′ in FIG. 28, and/or a dashed-box D4′ in FIG. 29). Referring to FIGS. 24-25 in conjunction with FIGS. 26-29, in some embodiments, certain structural features including the encapsulant 400 and the solder regions 3604 indicated by the dashed-box D′ depicted in FIG. 25 are stressed for illustration purposes, where the enlarged cross-sectional views shown in the dashed-box D1′ of FIG. 26, the dashed-box D2′ of FIG. 27, the dashed-box D3′ of FIG. 28 and the dashed-box D4′ of FIG. 29 are the various embodiments of the cross-sectional view of the dashed-box D′ depicted in FIG. 25. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 24, in some embodiments, a cutting process is performed to form a plurality of openings O2 in the encapsulant 400 within the section G70 of each region R1, following the process as described in FIG. 7. As shown in FIG. 24, the solder regions 3604 are not yet accessibly revealed by the encapsulant 400, for example. The details of the cutting process have been previously described in FIGS. 8-12, and thus are not repeated herein for brevity. In some embodiments, act 4051 can be consistent with FIG. 24. In a non-limiting example, the cutting process may include a single one cut or multiple cuts with a common cutting depth (see FIG. 26), where topmost points of the encapsulant 400 (resulted in the single one cut or the different cuts with the common cutting depth) are disposed at the same plane P5. In a non-limiting example, the cutting process may include multiple cuts with different cutting depths (see FIG. 27), where topmost points of the encapsulant 400 (resulted in different cuts without the common cutting depth) are disposed at the different planes P6, P7 and P8.

Referring to FIG. 25, in some embodiment, a laser drill process is performed to form a plurality of openings O3 in the encapsulant 400 within the section G70 of each region R1 and only overlying the solder regions 3604. As shown in FIG. 25, the solder regions 3604 are accessibly revealed by the openings O3 formed in the encapsulant 400, for example. In some embodiments, act 4052 can be consistent with FIG. 25. In some embodiments, the surface roughness of the illustrated top surfaces S3604 of the solder regions 3604 exposed by the openings O3 is small enough to be considered insignificant as compared to the surface roughness (Ra) of the illustrated top surfaces S400 of the encapsulant 400 outside the openings O3 within the opening O2, also see FIG. 26 and FIG. 27. That is to say, after laser drilling, the surface roughness of the illustrated top surfaces S3604 of the solder regions 3604 exposed by the openings O3 is insignificant, and thus the illustrated top surfaces S3604 of the solder regions 3604 exposed by openings O3 are considered as smooth surfaces.

In addition, a reflow process may be performed on the structure of FIG. 26 and/or the structure of FIG. 27 to re-shape the solder regions 3604, where the topmost surfaces S3604 (e.g., smooth planar surfaces) of the solder regions 3604 exposed by the openings O3 may be shaped into a desired shape, see FIG. 28 and FIG. 29. For example, after reflowing, the topmost surfaces S3604 of the solder regions 3604 exposed by the openings O3 each include a smoothly curved surface, e.g., a convex surface as shown in FIG. 28 and FIG. 29.

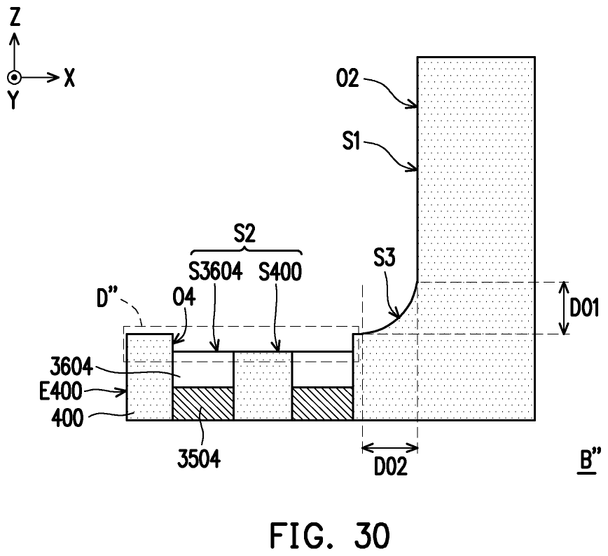

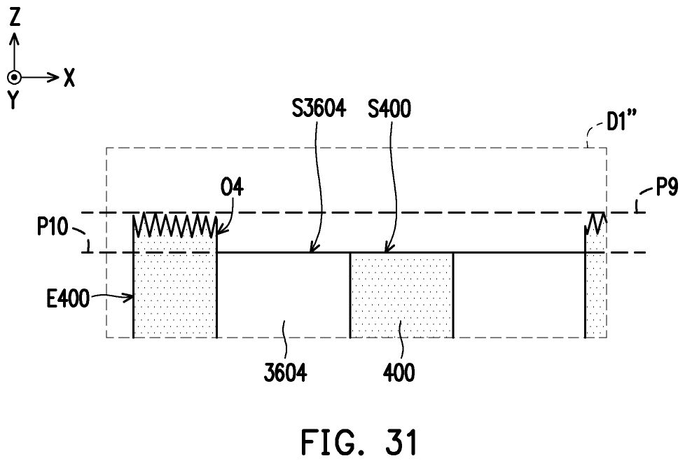

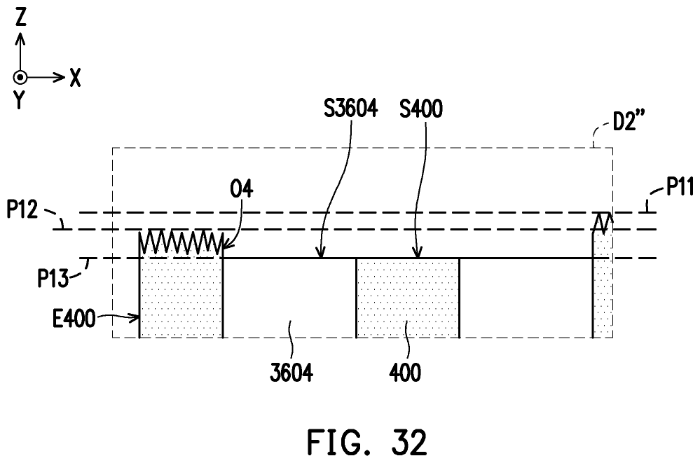

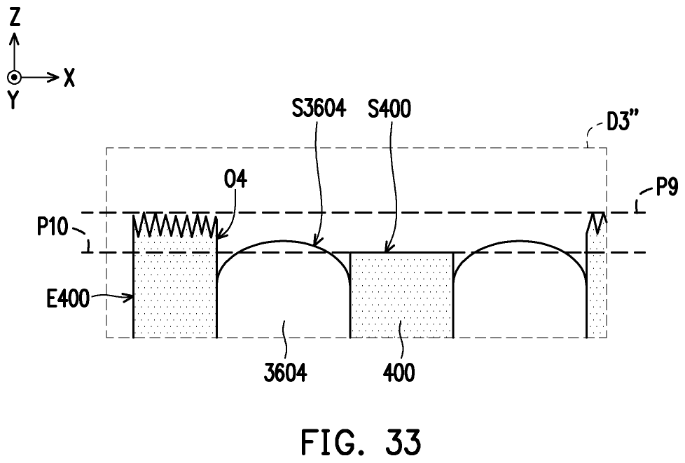

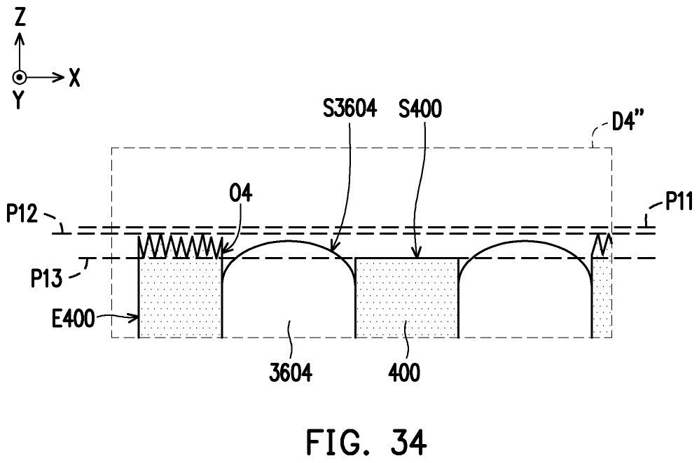

In the above embodiments shown in FIG. 25 in conjunction with FIGS. 26-29, the arrangement of the openings O2 and the openings O3 is in form of a one-to-multiple configuration, where a single one opening O2 corresponds to multiple openings O3. That is to say, in a vertical projection along the direction Z, multiple openings O3 overlap with one opening O2. However, the disclosure is not limited thereto; the openings O3 in the section G70 of each region R1 may be replaced by one opening O4. FIG. 30 is a schematically enlarged, cross-sectional view of an intermediate stage in a manufacturing method of a semiconductor package in accordance with some embodiments of the disclosure, showing a cutting region which is a predetermined location of an optical die integrated with the semiconductor package, which is outlined by a dashed-box B depicted in FIG. 8 (e.g., denoted as B″ in FIG. 30). FIG. 31 through FIG. 34 are schematically enlarged, cross-sectional views showing various embodiments of an uppermost surface of an encapsulant and an uppermost surface of a solder region at the cutting region of FIG. 30, which are outlined by a dashed-box D″ depicted in FIG. 30 (e.g., a dashed-box D1″ in FIG. 31, a dashed-box D2″ in FIG. 32, a dashed-box D3″ in FIG. 33, and/or a dashed-box D4″ in FIG. 34). Referring to FIG. 30 in conjunction with FIGS. 31-34, in some embodiments, certain structural features including the encapsulant 400 and the solder regions 3604 indicated by the dashed-box D″ depicted in FIG. 30 are stressed for illustration purposes, where the enlarged cross-sectional views shown in the dashed-box D1″ of FIG. 31, the dashed-box D2″ of FIG. 32, the dashed-box D3″ of FIG. 33 and the dashed-box D4″ of FIG. 34 are the various embodiments of the cross-sectional view of the dashed-box D″ depicted in FIG. 30. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 30, a laser drill process is performed to form one opening O4 in the encapsulant 400 within the section G70 of each region R1, following the process (e.g. act 4051) of FIG. 24. As shown in FIG. 30, the solder regions 3604 within the section G70 of each region R1 are accessibly revealed by the opening O4 formed in the encapsulant 400, for example. In some embodiments, act 4052 can be consistent with FIG. 30. In some embodiments, the surface roughness of the illustrated top surfaces S3604 of the solder regions 3604 and the surface roughness of the illustrated top surfaces S400 of the encapsulant 400 exposed by the opening O4 are small enough to be considered insignificant as compared to the surface roughness (Ra) of the illustrated top surfaces S400 of the encapsulant 400 outside the opening O4 and within the opening O2, also see FIG. 31 and FIG. 32. That is to say, after laser drilling, the surface roughness of the illustrated top surfaces S3604 of the solder regions 3604 and the surface roughness of the illustrated top surfaces S400 of the encapsulant 400 exposed by the opening O4 are insignificant, and thus the illustrated top surfaces S3604 of the solder regions 3604 and the illustrated top surfaces S400 of the encapsulant 400 exposed by the opening O4 are considered as smooth surfaces.

In FIG. 30 and FIG. 31, for example, a cutting process of a single one cut or multiple cuts with a common cutting depth is adopted in act 4051, where topmost points of the encapsulant 400 (resulted in the single one cut or the different cuts with the common cutting depth) are disposed at the same plane P9; and the, the laser drill process is adopted in act 4502 to form the opening O4 exposing the solder regions 3604 and a part of the encapsulant 400, where topmost points of the encapsulant 400 exposed by opening O4 are disposed at the same plane P10, and the plane P10 is below the plane P9.

In FIG. 30 and FIG. 32, for example, a cutting process of multiple cuts with different cutting depths is adopted in act 4051, where topmost points of the encapsulant 400 (resulted in different cuts without the common cutting depth) are disposed at the different planes P11 and P12; and the, the laser drill process is adopted in act 4502 to form the opening O4 exposing the solder regions 3604 and a part of the encapsulant 400, where topmost points of the encapsulant 400 exposed by opening O4 are disposed at the same plane P13, and the plane P13 is below the planes P11 and P12.

In addition, a reflow process may be performed on the structure of FIG. 31 and/or the structure of FIG. 32 to re-shape the solder regions 3604, where the topmost surfaces S3604 (e.g., smooth planar surfaces) of the solder regions 3604 exposed by the opening O4 may be shaped into a desired shape, see FIG. 33 and FIG. 34. For example, after reflowing, the topmost surfaces S3604 of the solder regions 3604 exposed by the opening O4 each include a smoothly curved surface, e.g., a convex surface as shown in FIG. 33 and FIG. 34.

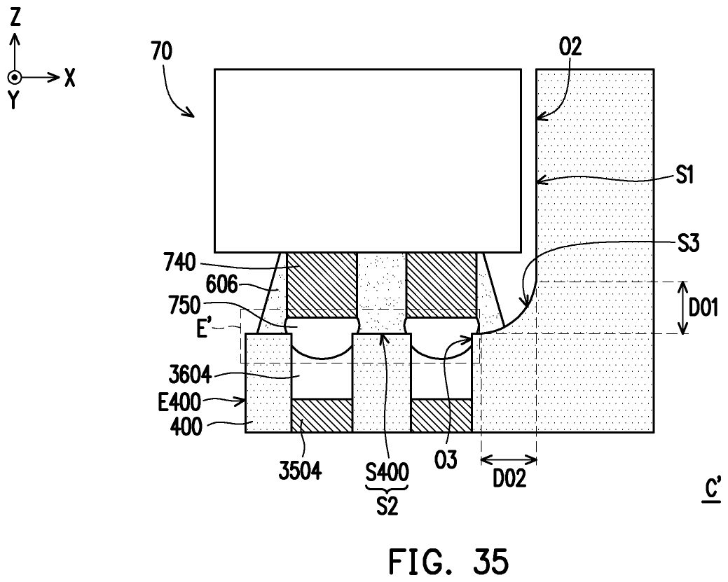

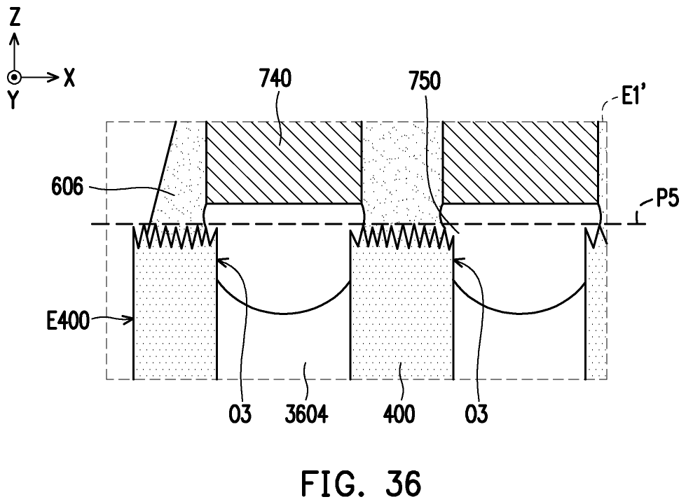

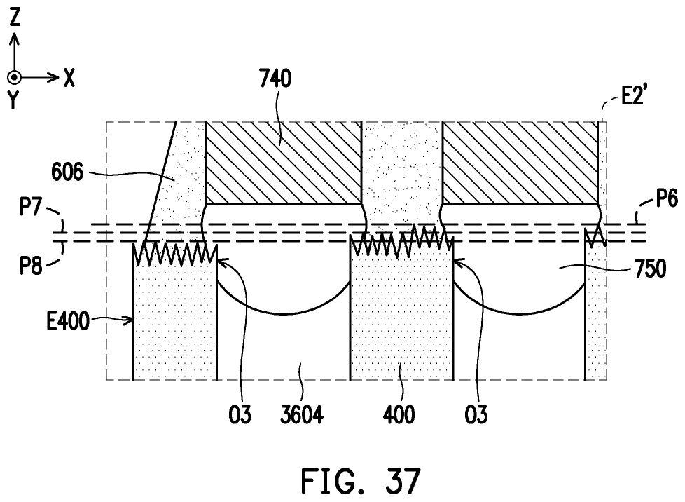

FIG. 35 is a schematically enlarged, cross-sectional view showing a bonding configuration between a semiconductor element and an optical die integrated with a semiconductor package in accordance with some embodiments of the disclosure, which is outlined by a dashed-box C depicted in FIG. 17 (e.g., denoted as C′ in FIG. 35). FIG. 36 through FIG. 37 are schematically enlarged, cross-sectional views showing various embodiments of an uppermost surface of an encapsulant near the bonding configuration of FIG. 35, which are outlined by a dashed-box E′ depicted in FIG. 35 (e.g., a dashed-box E1′ in FIG. 36 and/or a dashed-box E2′ in FIG. 37). Referring to FIG. 35 in conjunction with FIGS. 36-37, in some embodiments, certain structural features including a part of the underfill 606, the conductive vias 740, the solder regions 750, the encapsulant 400, the solder regions 3604 indicated by the dashed-box E′ depicted in FIG. 35 are stressed for illustration purposes, where the enlarged cross-sectional views shown in the dashed-box E1′ of FIG. 36 and the dashed-box E2′ of FIG. 37 are the various embodiments of the cross-sectional view of the dashed-box E′ depicted in FIG. 35. The elements similar to or substantially the same as the elements described previously will use the same reference numbers, and certain details or descriptions (e.g., the materials, formation processes, positioning configurations, electrical connections, etc.) of the same elements would not be repeated herein.

In the embodiments of which the enlarged cross-sectional views shown in the dashed-box D1′ of FIG. 26 or the dashed-box D3′ of FIG. 28 is adopted, the illustrated top surface S400 of the encapsulant 400 remaining in the opening O2 (and outside the openings O3) still maintains the same topography (e.g., the predetermined surface roughness (Ra) and the plane P5) as discussed previously, after bonding the optical die 70 onto the semiconductor element 300 by flip-chip process, see FIG. 36. In the embodiments of which the enlarged cross-sectional views shown in the dashed-box D2′ of FIG. 27 or the dashed-box D4′ of FIG. 29 is adopted, the illustrated top surface S400 of the encapsulant 400 remaining in the opening O2 (and outside the openings O3) still maintains the same topography (e.g., the predetermined surface roughness (Ra) and the planes P6-P8) as discussed previously, after bonding the optical die 70 onto the semiconductor element 300 by flip-chip process, see FIG. 37. Although clear interfaces between the solder regions 750 and the solder regions 3604 are shown in FIGS. 35-37, the clear interfaces may not presented if the solder regions 750 and the solder regions 3604 being made of same material and bonded to each other under a proper reflowed temperature.

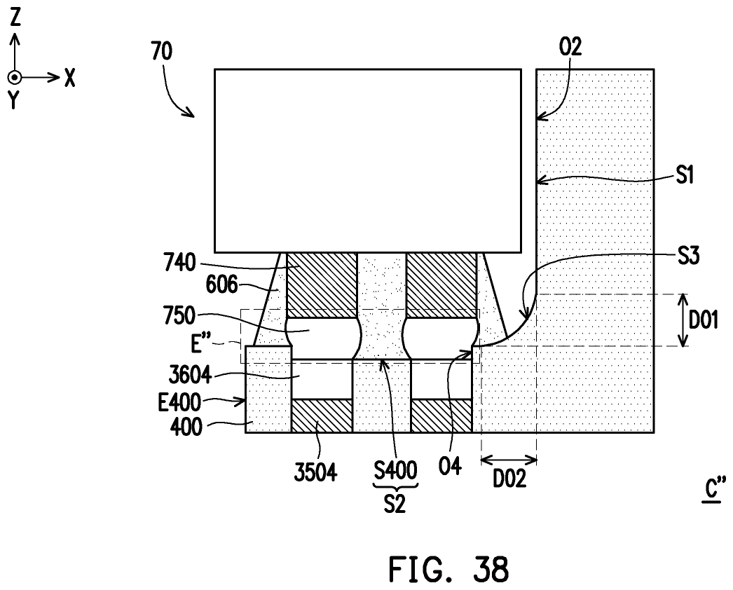

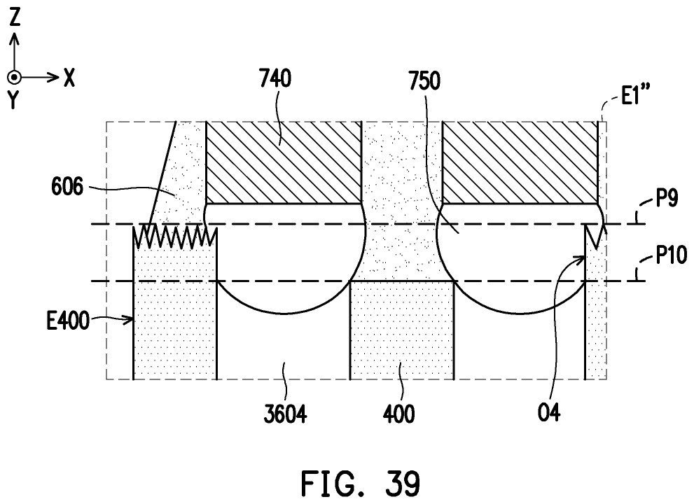

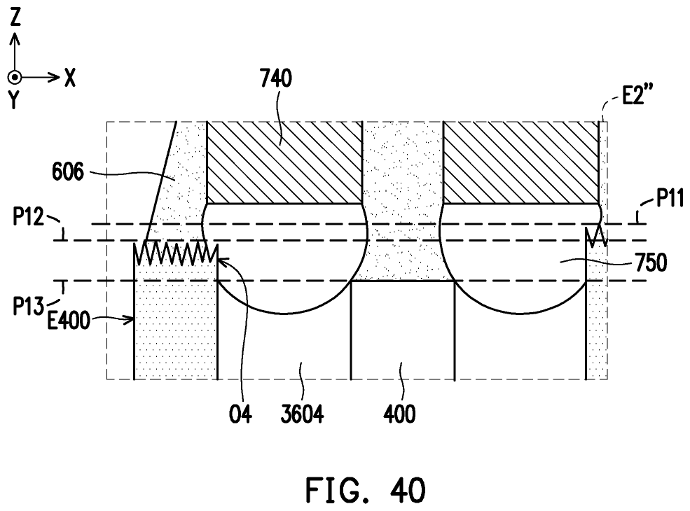

FIG. 38 is a schematically enlarged, cross-sectional view showing a bonding configuration between a semiconductor element and an optical die integrated with a semiconductor package in accordance with some embodiments of the disclosure, which is outlined by a dashed-box C depicted in FIG. 17 (e.g., denoted as C″ in FIG. 38). FIG. 39 through FIG. 40 are schematically enlarged, cross-sectional views showing various embodiments of an uppermost surface of an encapsulant near the bonding configuration of FIG. 38, which are outlined by a dashed-box E″ depicted in FIG. 38 (e.g., a dashed-box E1″ in FIG. 39 and/or a dashed-box E2″ in FIG. 40). Referring to FIG. 38 in conjunction with FIGS. 39-40, in some embodiments, certain structural features including a part of the underfill 606, the conductive vias 740, the solder regions 750, the encapsulant 400, the solder regions 3604 indicated by the dashed-box E″ depicted in FIG. 38 are stressed for illustration purposes, where the enlarged cross-sectional views shown in the dashed-box E1″ of FIG. 39 and the dashed-box E2″ of FIG. 40 are the various embodiments of the cross-sectional view of the dashed-box E″ depicted in FIG. 38. The elements similar to or substantially the same as the elements described previously will use the same reference numbers, and certain details or descriptions (e.g., the materials, formation processes, positioning configurations, electrical connections, etc.) of the same elements would not be repeated herein.

In the embodiments of which the enlarged cross-sectional views shown in the dashed-box D1″ of FIG. 31 or the dashed-box D3″ of FIG. 33 is adopted, the illustrated top surface S400 of the encapsulant 400 remaining in the opening O2 (and outside the opening O4) still maintains the same topography (e.g., the predetermined surface roughness (Ra) and the planes P9-P10) as discussed previously, after bonding the optical die 70 onto the semiconductor element 300 by flip-chip process, see FIG. 39. In the embodiments of which the enlarged cross-sectional views shown in the dashed-box D2″ of FIG. 32 or the dashed-box D4″ of FIG. 34 is adopted, the illustrated top surface S400 of the encapsulant 400 remaining in the opening O2 (and outside the opening O4) still maintains the same topography (e.g., the predetermined surface roughness (Ra) and the planes P11-P13) as discussed previously, after bonding the optical die 70 onto the semiconductor element 300 by flip-chip process, see FIG. 40. Although clear interfaces between the solder regions 750 and the solder regions 3604 are shown in FIGS. 38-40, the clear interfaces may not presented if the solder regions 750 and the solder regions 3604 being made of same material and bonded to each other under a proper reflowed temperature.

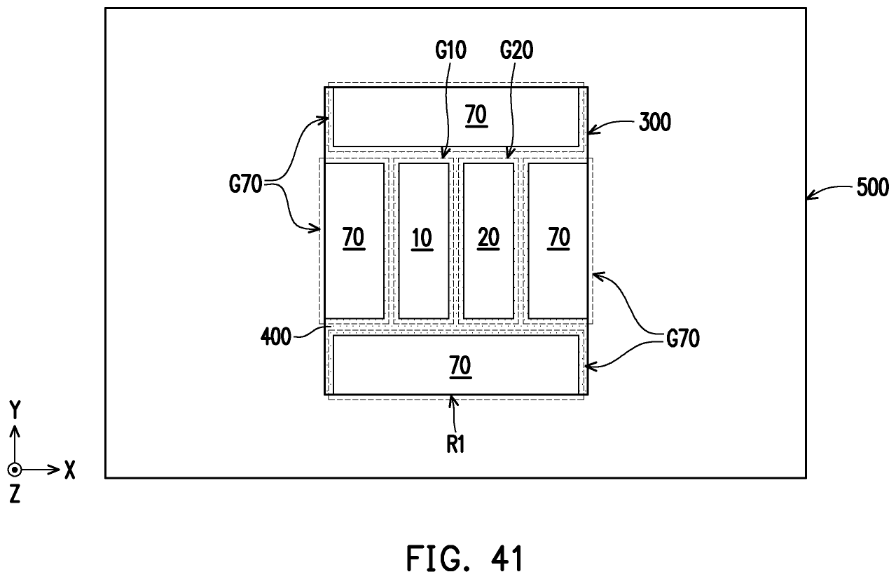

In the above embodiments, for each region R1, there is only one optical die 70 disposed at an edge of the semiconductor package 1000. However, the disclosure is not limited thereto; the optical die 70 may be more than one. FIG. 41 through FIG. 48 are schematically plane views showing various embodiments of an arrangement of an optical die and a semiconductor die included in a semiconductor package in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein. It is appreciated that, in various embodiments of FIGS. 41-48, certain structural features including one or more optical dies 70, one or more semiconductor die 10, and/or one or more semiconductor die 20 included in one semiconductor package having a CoWoS structure (involving the substrate 500, the semiconductor element 300 and the encapsulant 400 for each region R1) are stressed for illustration purposes, the rest components of the semiconductor package previously described in FIG. 1 through FIG. 40 are omitted for easy illustration; the disclosure is not limited thereto.

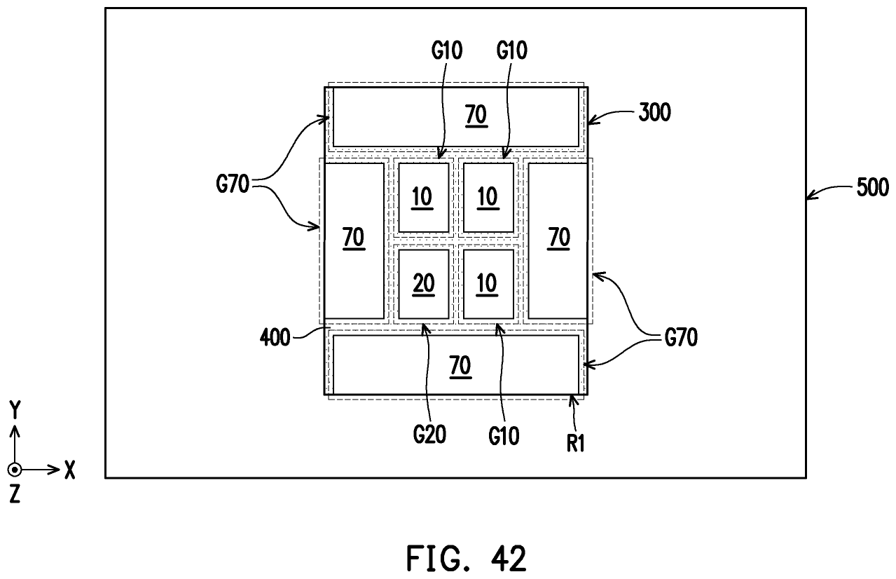

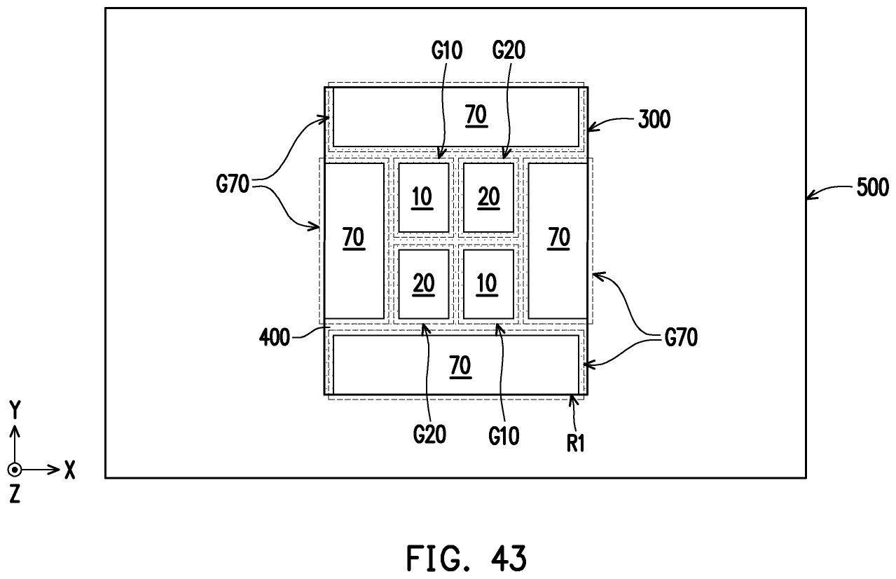

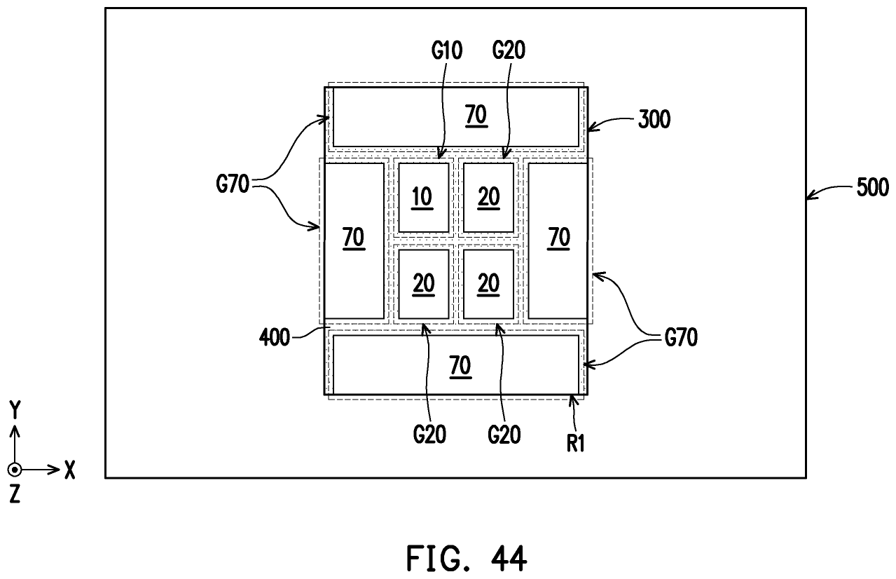

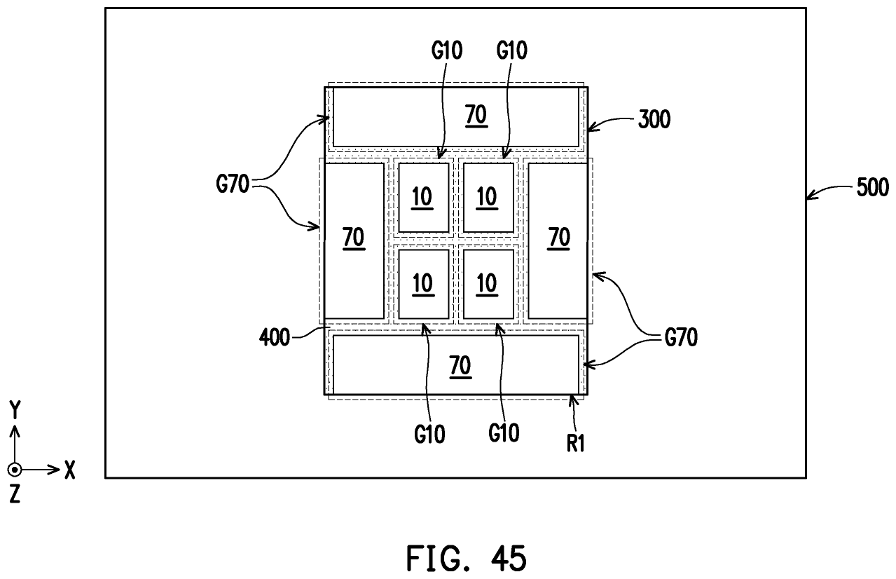

In some embodiments, the region R1 include more than one section G70, where the sections G70 are disposed at all edges of the region R1, see FIG. 41. Furthermore, in FIG. 41, the region R1 may include one section G10 having only one semiconductor die 10 and only one section G20 having only one semiconductor die 20. However, the disclosure is not limited thereto; alternatively, the section G10 may include multiple semiconductor dies 10 while the section G20 may include only one semiconductor die 20, the section G10 may include only one semiconductor die 10 while the section G20 may include multiple semiconductor dies 20, or the section G10 may include multiple semiconductor dies 10 while the section G20 may include multiple semiconductor dies 20. Or alternatively, the region R1 may include multiple sections G10 and only one section G20 (see FIG. 42), multiple sections G10 and multiple sections G20 (see FIG. 43), only one section G10 and multiple sections G20 (see FIG. 44), or multiple sections G10 without section G20 (see FIG. 45); where the number of the semiconductor dies in sections G10 and G20 may be selected based on demand and design layout. In addition, if considering multiple sections G10 and/or G20 are included in one region R1, different sections G10 may include different numbers, different types, different sizes, and/or different shapes of semiconductor dies (e.g., 10); and/or, different sections G20 may include different numbers, different types, different sizes, and/or different shapes of semiconductor dies (e.g., 20).

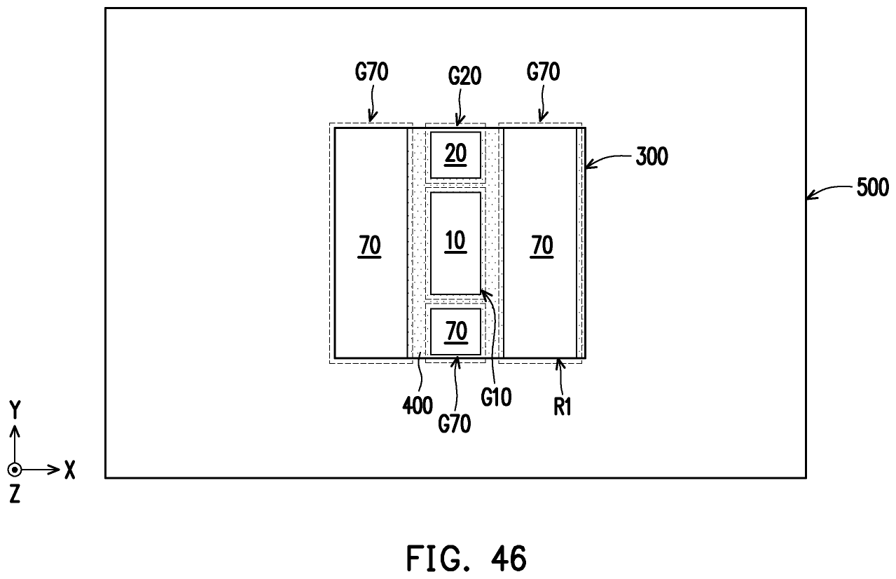

In some embodiments, the region R1 include more than one section G70, where the sections G70 are disposed at three edges of the region R1, see FIG. 46. Furthermore, in FIG. 46, the region R1 may include one section G10 having only one semiconductor die 10 and only one section G20 having only one semiconductor die 20. However, the disclosure is not limited thereto; alternatively, the section G10 may include multiple semiconductor dies 10 while the section G20 may include only one semiconductor die 20, the section G10 may include only one semiconductor die 10 while the section G20 may include multiple semiconductor dies 20, or the section G10 may include multiple semiconductor dies 10 while the section G20 may include multiple semiconductor dies 20. Or alternatively, the region R1 may include multiple sections G10 and only one section G20, multiple sections G10 and multiple sections G20, only one section G10 and multiple sections G20, or multiple sections G10 without section G20; where the number of the semiconductor dies in sections G10 and G20 may be selected based on demand and design layout. In addition, if considering multiple sections G10 and/or G20 are included in one region R1, different sections G10 may include different numbers, different types, different sizes, and/or different shapes of semiconductor dies (e.g., 10); and/or, different sections G20 may include different numbers, different types, different sizes, and/or different shapes of semiconductor dies (e.g., 20).

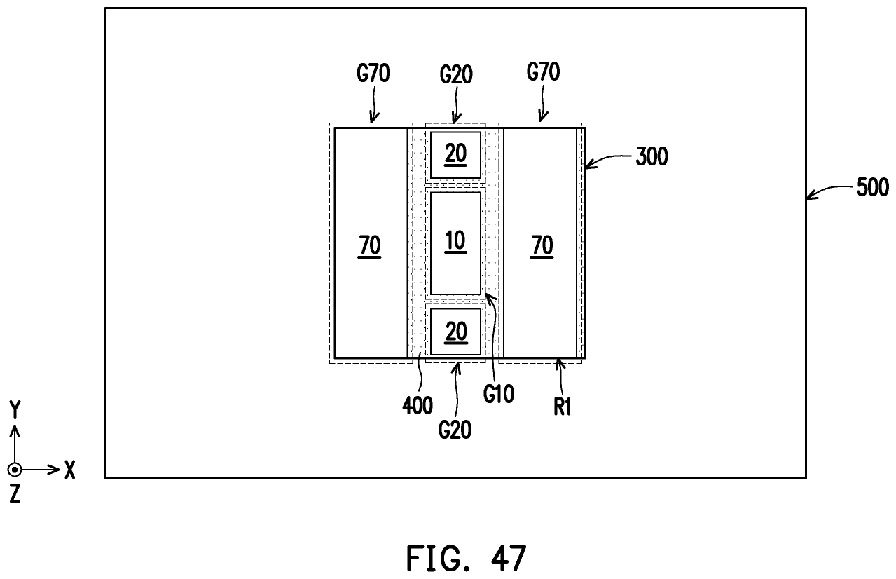

In some embodiments, the region R1 include more than one section G70, where the sections G70 are disposed at two opposite edges of the region R1, see FIG. 47. Furthermore, in FIG. 47, the region R1 may include one section G10 having only one semiconductor die 10 and multiple sections G20 each having only one semiconductor die 20. However, the disclosure is not limited thereto; alternatively, the section G10 may include multiple semiconductor dies 10 while the section G20 may include only one semiconductor die 20, the section G10 may include only one semiconductor die 10 while the section G20 may include multiple semiconductor dies 20, or the section G10 may include multiple semiconductor dies 10 while the section G20 may include multiple semiconductor dies 20. Or alternatively, the region R1 may include multiple sections G10 and only one section G20, multiple sections G10 and multiple sections G20, only one section G10 and multiple sections G20, or multiple sections G10 without section G20; where the number of the semiconductor dies in sections G10 and G20 may be selected based on demand and design layout. In addition, if considering multiple sections G10 and/or G20 are included in one region R1, different sections G10 may include different numbers, different types, different sizes, and/or different shapes of semiconductor dies (e.g., 10); and/or, different sections G20 may include different numbers, different types, different sizes, and/or different shapes of semiconductor dies (e.g., 20).

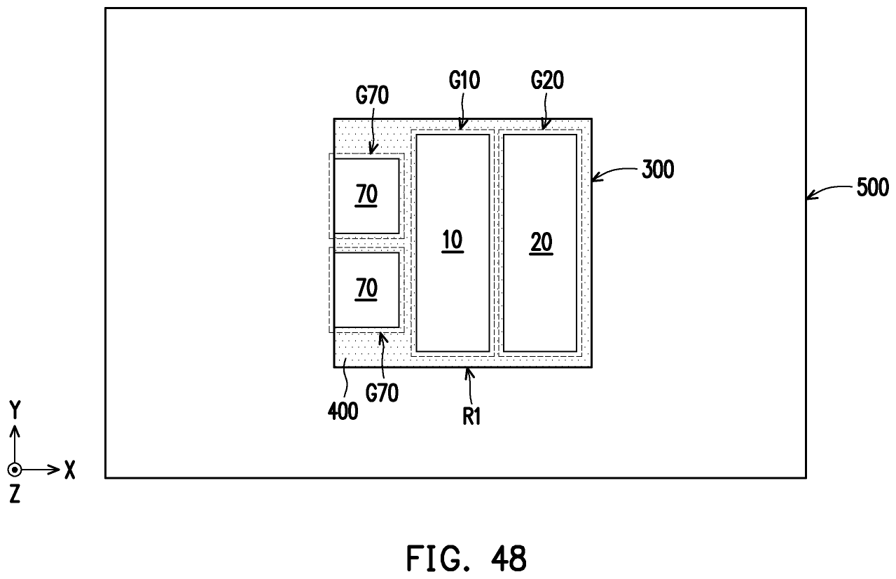

In some embodiments, each section G70 of the region R1 include more than one optical die, see FIG. 48. Furthermore, in FIG. 41, the region R1 may include one section G10 having only one semiconductor die 10 and one section G20 having only one semiconductor die 20. However, the disclosure is not limited thereto; alternatively, the section G10 may include multiple semiconductor dies 10 while the section G20 may include only one semiconductor die 20, the section G10 may include only one semiconductor die 10 while the section G20 may include multiple semiconductor dies 20, or the section G10 may include multiple semiconductor dies 10 while the section G20 may include multiple semiconductor dies 20. Or alternatively, the region R1 may include multiple sections G10 and only one section G20, multiple sections G10 and multiple sections G20, only one section G10 and multiple sections G20, or one or more sections G10 without section G20; where the number of the semiconductor dies in sections G10 and G20 may be selected based on demand and design layout. In addition, if considering multiple sections G10 and/or G20 are included in one region R1, different sections G10 may include different numbers, different types, different sizes, and/or different shapes of semiconductor dies (e.g., 10); and/or, different sections G20 may include different numbers, different types, different sizes, and/or different shapes of semiconductor dies (e.g., 20).

In the disclosure, the forming processes of opening O2, openings O3, and opening O4 in the manufacture of a semiconductor package having a CoWoS structure integrated with an optical die (or package) are simple and effective. With such, the implement of integrating one or more optical dies (or packages) to the CoWoS structure is greatly simplified, thereby improving the performance of the semiconductor package, by enabling faster data transfer over long distances and providing bandwidth enlargement.

In accordance with some embodiments, a semiconductor package includes a semiconductor element, at least one electronic die, at least one optical die, an encapsulant, and a substrate. The semiconductor element has a first side and a second side opposing to the first side. The at least one electronic die is disposed over the first side. The at least one optical die is disposed over the first side and next to the at least one electronic die. The encapsulant is disposed on the first side and covers the at least one electronic die, where a sidewall of the at least one optical die is distant from the encapsulant, and a sidewall of the encapsulant is aligned with a sidewall of the semiconductor element. The substrate is disposed over the second side, where the at least one electronic die is electrically coupled to the substrate and the at least one optical die through the semiconductor element.

In accordance with some embodiments, a semiconductor package includes a first semiconductor die, a second semiconductor die, a third semiconductor die, a semiconductor element, a first insulating encapsulation, a second insulating encapsulation, and a substrate. The first semiconductor die, the second semiconductor die, and the third semiconductor die are disposed over and electrically coupled to the semiconductor element. The first insulating encapsulation is disposed over the semiconductor element and covers the second semiconductor die and the third semiconductor die. The second insulating encapsulation is disposed between the semiconductor element and the first semiconductor die, and the first insulating encapsulation connects to the second insulating encapsulation, where a first thickness of the first insulating encapsulation is greater than a second thickness of the second insulating encapsulation. The substrate is disposed over and electrically coupled to the semiconductor element, where the semiconductor element is between the first semiconductor die and the substrate.

In accordance with some embodiments, a method of manufacturing a semiconductor package includes the following steps: providing a semiconductor element with a first group of conductive pads and a second group of conductive pads; disposing at least one die on the semiconductor element through the first group of conductive pads; encapsulating the at least one die in an encapsulant; trimming the encapsulant to form a first region and a second region, the second region being confined by an opening exposing the second group of conductive pads; performing a dicing process to form a chip-on-wafer structure; mounting the chip-on-wafer structure to a substrate to form the semiconductor package having a chip-on-wafer-on-substrate structure; and disposing the at least one optical die on the chip-on-wafer-on-substrate structure through the second group of conductive pads, so to integrate the at least one optical die with the semiconductor package having the chip-on-wafer-on-substrate structure, the at least one optical die being distant from the encapsulant.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor package, comprising:
a semiconductor element, having a first side and a second side opposing to the first side;
at least one electronic die, disposed over the first side;
at least one optical die, disposed over the first side and next to the at least one electronic die;
an encapsulant, disposed on the first side and covering the at least one electronic die, wherein a sidewall of the at least one optical die is distant from the encapsulant, and a sidewall of the encapsulant is aligned with a sidewall of the semiconductor element; and
a substrate, disposed over the second side, wherein the at least one electronic die is electrically coupled to the substrate and the at least one optical die through the semiconductor element.

2. The semiconductor package of claim 1, wherein the encapsulant further comprises an extended portion disposed between the semiconductor element and the at least one optical die, and the at least one optical die is further free from the extended portion of the encapsulant,
wherein a thickness of the extended portion of the encapsulant is less than a thickness of the encapsulant covering the at least one electronic die.

3. The semiconductor package of claim 1, wherein a portion of the encapsulant further between the semiconductor element and the at least one optical die has an first outermost surface with a first surface roughness, and a portion of the encapsulant surrounding the at least one electronic die has an second outermost surface with a second surface roughness, wherein the first outermost surface is free from the semiconductor element, and the second outermost surface is level with a surface of a substrate of the at least one electronic die has an second outermost surface with a second surface roughness, and wherein the first surface roughness is greater than the second surface roughness.

4. The semiconductor package of claim 1, wherein the at least one electronic die comprises at least one first die and at least one second die,
wherein the at least one first die and the at least one second die are encapsulated in the encapsulant, and the at least one first die and the at least one second die are electrically coupled to the semiconductor element.

5. The semiconductor package of claim 4, wherein a portion of the encapsulant further between the semiconductor element and the at least one optical die has an first outermost surface with a first surface roughness, and a portion of the encapsulant further between the at least one first die and the at least one second die has an second outermost surface with a second surface roughness, wherein the first outermost surface and the second outermost surface are free from the semiconductor element, and the first surface roughness is greater than the second surface roughness.

6. The semiconductor package of claim 4, wherein the at least one first die comprises one or more logic dies, and the at least one second die comprises one or more memory dies, and
wherein the semiconductor element comprises an interposer.

7. The semiconductor package of claim 1, wherein the encapsulant comprises at least one first portion disposed between the semiconductor element and the at least one optical die and a second portion surrounding the at least one electronic die, and the first portion is connected to the second portion,
wherein in a vertical projection on a plane view, the at least one first portion is disposed near and extends along at least one edge of the semiconductor element.

8. A semiconductor package, comprising:
a first semiconductor die and a second semiconductor die, disposed over and electrically coupled to a semiconductor element;
a first insulating encapsulation, disposed over the semiconductor element and covering the second semiconductor die;
a second insulating encapsulation, disposed between the semiconductor element and the first semiconductor die, the first insulating encapsulation connecting to the second insulating encapsulation, wherein a first thickness of the first insulating encapsulation is greater than a second thickness of the second insulating encapsulation; and
a substrate, disposed over and electrically coupled to the semiconductor element, the semiconductor element being between the first semiconductor die and the substrate.

9. The semiconductor package of claim 8, further comprising at least one of:
a first underfill, disposed between the first semiconductor die and the second insulating encapsulation and wrapping a plurality of first bonding structures disposed between and physically connecting the first semiconductor die and the semiconductor element;
a second underfill, disposed between the second semiconductor die and the semiconductor element and wrapping a plurality of second bonding structures disposed between and physically connecting the second semiconductor die and the semiconductor element; or
a third underfill, disposed between the semiconductor element and the substrate and wrapping third bonding structures disposed between and physically connecting the semiconductor element and the substrate.

10. The semiconductor package of claim 8, further comprises:
a plurality of first conductive terminals, disposed between and electrically coupling the semiconductor element and the substrate;
an underfill, disposed between the semiconductor element and the substrate, the underfill wrapping the plurality of first conductive terminals; and
a plurality of second conductive terminals, disposed over and electrically coupling the substrate, wherein the substrate is between the plurality of first conductive terminals and the plurality of second conductive terminals,
wherein the semiconductor element comprises an interposer.

11. The semiconductor package of claim 8, further comprising:
a third semiconductor die, disposed over and electrically coupled to the semiconductor element and next to the second semiconductor die, wherein the third semiconductor die is covered by the first insulating encapsulation; and
a fourth underfill, disposed between the third semiconductor die and the semiconductor element and wrapping a plurality of fourth bonding structures disposed between and physically connecting the third semiconductor die and the semiconductor element.

12. The semiconductor package of claim 11,
wherein the first semiconductor die comprises one or more optical dies, the second semiconductor die comprises one or more logic dies, and the third semiconductor die comprises one or more memory dies,
wherein the first semiconductor die comprises one or more optical dies, the second semiconductor die comprises one or more first logic dies, and the third semiconductor die comprises one or more second logic dies, or
wherein the first semiconductor die comprises one or more optical dies, the second semiconductor die comprises one or more first memory dies, and the third semiconductor die comprises one or more second memory dies.

13. The semiconductor package of claim 8, wherein in a stacking direction of the first semiconductor die and the semiconductor element, the first insulating encapsulation has a first outermost surface away from the semiconductor element, and the second insulating encapsulation has a second outermost surface away from the semiconductor element,
wherein a first surface roughness of the first outermost surface is less than a second surface roughness of the second outermost surface.

14. The semiconductor package of claim 8, wherein in a stacking direction of the first semiconductor die and the semiconductor element, the second insulating encapsulation has a second outermost surface away from the semiconductor element, and the second outermost surface comprises two or more portions respectively disposed at different heights.

15. A method of manufacturing a semiconductor package, comprising:
providing a semiconductor element with a first group of conductive pads and a second group of conductive pads;
disposing at least one die on the semiconductor element through the first group of conductive pads;
encapsulating the at least one die in an encapsulant;
trimming the encapsulant to form a first region and a second region, the second region being confined by an opening exposing the second group of conductive pads;
performing a dicing process to form a chip-on-wafer structure;
mounting the chip-on-wafer structure to a substrate to form the semiconductor package having a chip-on-wafer-on-substrate structure; and
disposing at least one optical die on the chip-on-wafer-on-substrate structure through the second group of conductive pads, so to integrate the at least one optical die with the semiconductor package having the chip-on-wafer-on-substrate structure, the at least one optical die being distant from the encapsulant.

16. The method of claim 15, wherein trimming the encapsulant to form the first region and the second region comprises:
performing a cutting process on the encapsulant, the cutting process comprising one cut or multiple cuts by blade sawing so to form the opening, wherein the opening exposes the second group of conductive pads from the encapsulant in the second region, and a surface roughness of an outermost surface of the encapsulant in the second region is greater than a surface roughness of an outermost surface of the encapsulant in the first region.

17. The method of claim 15, wherein trimming the encapsulant to form the first region and the second region comprises:
performing a cutting process on the encapsulant, the cutting process comprising one cut or multiple cuts by blade sawing so to form the opening, wherein a surface roughness of an outermost surface of the encapsulant in the second region is greater than a surface roughness of an outermost surface of the encapsulant in the first region; and
performing a laser drill process to remove portions of the encapsulant exposed by the opening and overlying the second group of conductive pads, so to form a plurality of first through holes exposing the second group of conductive pads from the encapsulant in the second region.

18. The method of claim 15, wherein trimming the encapsulant to form the first region and the second region comprises:
performing a cutting process on the encapsulant, the cutting process comprising one cut or multiple cuts by blade sawing so to form the opening, wherein a surface roughness of an outermost surface of the encapsulant in the second region is greater than a surface roughness of an outermost surface of the encapsulant in the first region; and
performing a laser drill process to remove a portion of the encapsulant exposed by the opening and overlying the second group of conductive pads and a portion of the encapsulant in the second region, so to form a second through holes exposing the second group of conductive pads from the encapsulant in the second region,
wherein the surface roughness of the outermost surface of the encapsulant in the second region and outside the second through hole is greater than a surface roughness of an outermost surface of the encapsulant in the second region and within the second through hole.

19. The method of claim 15, wherein prior to trimming the encapsulant to form the first region and the second region and after encapsulating the at least one die in the encapsulant, the method further comprises:
forming a plurality of conductive terminals on a side of the semiconductor element, the side is facing away from the at least one die,
wherein the plurality of conductive terminals are electrically coupled to the semiconductor element and the substrate and further electrically coupled to the at least one die through the semiconductor element.

20. The method of claim 15, wherein prior to performing the dicing process and after trimming the encapsulant to form the first region and the second region, the method further comprises:
performing a reflowing process on the second group of conductive pads exposed by the opening.
